(19) United States
(12) Patent Application Publication
(10) Pub. No.: US 2014/0191618 A1
(43) Pub. Date: Jul. 10, 2014

(54) POLING TREATMENT METHOD, PLASMA POLING DEVICE, PIEZOELECTRIC BODY AND MANUFACTURING METHOD THEREOF, FILM FORMING DEVICE AND ETCHING DEVICE, AND LAMP ANNEALING DEVICE

(71) Applicants: Takeshi Kijima, Chiba (JP); Yuuji Honda, Chiba (JP)

(72) Inventors: Takeshi Kijima, Chiba (JP); Yuuji Honda, Chiba (JP)

(73) Assignee: YOUTEC CO., LTD., Chiba (JP)

(21) Appl. No.: 14/123,138

(22) PCT Filed: Jun. 7, 2011
(86) PCT No.: PCT/JP2011/063022

§ 371 Date: Feb. 25, 2014

(51) Int. Cl. H01L 41/257; B23K 10/00; H01L 21/324

(52) U.S. Cl. CPC H01L 41/257; H01L 21/324; B23K 10/003
USPC 310/357; 29/25.35; 392/416; 219/121.4; 204/298.07; 156/345.27; 118/723 R

(57) ABSTRACT

A plasma poling device includes a holding electrode (4) which is disposed in a poling chamber (1) and holds a substrate to be poled (2), an opposite electrode (7) which is disposed in the poling chamber and disposed facing the substrate to be poled held on the holding electrode, a power source (6) electrically connected to one electrode of the holding electrode and the opposite electrode, a gas supply mechanism supplying a plasma forming gas into a space between the opposite electrode and the holding electrode, and a control unit controlling the power source and the gas supply mechanism. The control unit controls the power source and the gas supply mechanism so as to form a plasma at a position facing the substrate to be poled and to apply a poling treatment to the substrate to be poled.

### TECHNICAL FIELD

The present invention relates to a poling treatment method of performing poling treatment using plasma, a plasma poling device, a piezoelectric body and a manufacturing method thereof, a film forming device and etching device, and a lamp annealing device.

### BACKGROUND ART

FIG. 19 is a schematic diagram showing a conventional poling device.

A crystal 33 is sandwiched between a pair of electrodes 35 which is configured with two parallel flat plates of 10×10 mm², at the center thereof so that an electric field is applied in a direction to which mechanical poling is not applied. Then, the crystal 33 is dipped into oil 36 in an oil bath 37 together with the electrodes 35, and the oil 36 in which the crystal 33 is dipped is heated to 125° C. by a heater 38. After a predetermined temperature has been reached, a DC electric field of 1 kV/cm is applied for 10 hours across the electrodes 35 by a high voltage power source 39 via a lead wire 40. Thereby, a poling treatment is applied to the crystal 33 (see patent document 1, for example).

The above conventional poling treatment method is a wet method in which an object to be poled is dipped in oil in a state sandwiched between a pair of electrodes at the center thereof, and therefore the poling treatment is complicated.

### PRIOR ART DOCUMENT

### Patent Document

Patent document 1: Japanese Patent Laid-Open No. H10-177194 (Paragraph 0018 and FIG. 4)

### DISCLOSURE OF THE INVENTION

### Problem to be Solved by the Invention

One aspect of the present invention aims to provide any of a poling treatment method capable of performing poling treatment simply by a dry method, a plasma poling device, a piezoelectric body and a manufacturing method thereof, a film forming device and etching device, and a lamp annealing device.

Further, one aspect of the present invention aims to improve characteristics of a piezoelectric body or the like which has been poled in either the dry method or the wet method.

### Means for Solving the Problem

One aspect of the present invention is a poling treatment method for applying a poling treatment to a substrate to be poled at a first temperature, wherein the first temperature is not lower than a temperature at which a residual polarization value in a hysteresis curve of the substrate to be poled becomes 0%.

Further, in one aspect of the present invention, the poling treatment is applied to the substrate to be poled while a temperature is decreased from the first temperature to a second temperature or while the temperature is increased from the second temperature to the first temperature, and the second temperature is not lower than a temperature at which a residual polarization value becomes 50% of a residual polarization value at a room temperature in the hysteresis curve of the substrate to be poled, and also lower than the first temperature.

One aspect of the present invention is a poling treatment method for applying a poling treatment to a substrate to be poled at a first temperature, wherein the first temperature is not lower than a Curie temperature (preferably not lower than a temperature higher than the Curie temperature by 50° C.).

Further, in one aspect of the present invention, the poling treatment is applied to the substrate to be poled while a temperature is decreased from the first temperature to a second temperature, or while the temperature is increased from the second temperature to the first temperature, and the second temperature is not lower than 50° C. and also lower than the first temperature.

One aspect of the present invention is a poling treatment method for applying a poling treatment to a substrate to be poled at a first temperature, wherein

the first temperature is not lower than 100° C.

Further, in one aspect of the present invention, the poling treatment is applied to the substrate to be poled while a temperature is decreased from the first temperature to a second temperature, or while the temperature is increased from the second temperature to the first temperature, and

the second temperature is not lower than 100° C. and also lower than the first temperature.

In one aspect of the present invention, the substrate to be poled is the one in which a piezoelectric material film is formed on a silicon wafer having a thickness smaller than a thickness of the SEMI standard or a silicon wafer having a thickness not larger than 400 μm.

In one aspect of the present invention, the substrate to be poled is the one in which a piezoelectric material film is formed on any substrate of a metal substrate, a metal substrate having an oxidation resistance, a metal substrate having a heat resistance against the Curie temperature of the substrate to be poled or the temperature at which the residual polarization value in the hysteresis curve of the substrate to be poled becomes 0%, an iron based substrate (preferably a substrate such as an iron based alloy, a stainless series, and a SUS), and an Ni based substrate (e.g., a substrate such as an Ni alloy).

In one aspect of the present invention, the substrate to be poled is the one in which a piezoelectric material film is formed on any substrate of a glass substrate, a glass substrate having an oxidation resistance, and a glass substrate having a heat resistance against the Curie temperature of the substrate to be poled or the temperature at which the residual polarization value in the hysteresis curve of the substrate to be poled becomes 0%.

One aspect of the present invention is a poling treatment method for applying the poling treatment to the substrate to be poled, wherein

the substrate to be poled is the one in which a piezoelectric material film is formed on a silicon wafer having a thickness smaller than that of the SEMI standard or a silicon wafer having a thickness not larger than 400 μm.

Further, in one aspect of the present invention, preferably the substrate to be poled is a substrate including a dielectric body or an insulating body.

In one aspect of the present invention, preferably the substrate to be poled is a substrate including a piezoelectric body.

In one aspect of the present invention, preferably the substrate to be poled is a substrate including a pyroelectric body.

In one aspect of the present invention, preferably the substrate to be poled is a substrate including a ferroelectric body.

In one aspect of the present invention, plasma is formed at a position facing the substrate to be poled when the poling treatment is applied to the substrate to be poled.

In one aspect of the present invention, a DC voltage when a DC plasma is formed at a position facing the substrate to be poled, or a DC voltage component when a high frequency plasma is formed at a position facing the substrate to be poled, is ±50 V to ±2 kV.

In one aspect of the present invention, a pressure when the plasma is formed is 0.01 Pa to an air pressure.

In one aspect of the present invention, a plasma forming gas when the plasma is formed is one or more kinds of gas selected from a group of inert gas, H₂, N₂, O₂, F₂, CₓH_{y}, CₓF_{y}, and air.

One aspect of the present invention is a piezoelectric body, wherein the poling treatment is applied to the substrate to be poled by any of the above-described poling treatment methods and the substrate to be poled is provided with piezoelectric activity.

One aspect of the present invention is a plasma poling device including:

a poling chamber;

a holding electrode which is disposed in the poling chamber and holds a substrate to be poled;

an opposite electrode which is disposed in the poling chamber and disposed facing the substrate to be poled held on the holding electrode;

a power source electrically connected to one electrode of the holding electrode and the opposite electrode;

a gas supply mechanism supplying a plasma forming gas to a space between the opposite electrode and the holding electrode;

a temperature control mechanism controlling a temperature of the substrate to be poled held on the holding electrode; and

a control unit controlling the power source, the gas supply mechanism, and the temperature control mechanism, wherein

the control unit controls the power source, the gas supply mechanism, and the temperature control mechanism so as to set a temperature of the substrate to be poled to a first temperature not lower than a temperature at which a residual polarization value in a hysteresis curve of the substrate to be poled becomes 0%, and to form a plasma at a position facing the substrate to be poled and apply the poling treatment to the substrate to be poled.

One aspect of the present invention is a plasma poling device, comprising:

a poling chamber;

a holding electrode which is disposed in the poling chamber and holds a substrate to be poled;

an opposite electrode which is disposed in the poling chamber and disposed facing the substrate to be poled held on the holding electrode;

a first power source and a ground potential connected to the holding electrode via a first switch;

a second power source and the ground potential connected to the opposite electrode via a second switch;

a gas supply mechanism supplying a plasma forming gas to a space between the opposite electrode and the holding electrode;

a temperature control mechanism controlling a temperature of the substrate to be poled held on the holding electrode; and

a control unit controlling the first power source, the second power source, the gas supply mechanism, and the temperature control mechanism, wherein

the first switch switches from a first state in which the holding electrode and the first power source are electrically connected to each other, to a second state in which the holding electrode and the ground potential are electrically connected to each other,

the second switch switches from a third state in which the opposite electrode and the ground potential are electrically connected to each other, to a fourth state in which the opposite electrode and the second power source are electrically connected to each other, and

the control unit controls the first power source, the second power source, the gas supply mechanism, and the temperature control mechanism so as to set a temperature of the substrate to be poled to a first temperature not lower than a temperature at which a residual polarization value in a hysteresis curve of the substrate to be poled becomes 0%, and to form a plasma at a position facing the substrate to be poled and apply a poling treatment to the substrate to be poled, in the first state and the third state or in the second state and the fourth state.

Further, in one aspect of the present invention, the control unit is controlled so as to apply the poling treatment to the substrate to be poled, while decreasing a temperature from the first temperature to a second temperature or while increasing the temperature from the second temperature to the first temperature, and

the second temperature is not lower than a temperature at which the residual polarization value becomes 50% of a residual polarization value at a room temperature in the hysteresis curve of the substrate to be poled, and also lower than the first temperature.

One aspect of the present invention is a plasma poling device, comprising:

a poling chamber;

a holding electrode which is disposed in the poling chamber and holds a substrate to be poled;

an opposite electrode which is disposed in the poling chamber and disposed facing the substrate to be poled held on the holding electrode;

a power source electrically connected to one electrode of the holding electrode and the opposite electrode;

a gas supply mechanism supplying a plasma forming gas to a space between the opposite electrode and the holding electrode;

a temperature control mechanism controlling a temperature of the substrate to be poled held on the holding electrode; and

a control unit controlling the power source, the gas supply mechanism, and the temperature control mechanism, wherein

the control unit controls the power source, the gas supply mechanism, and the temperature control mechanism so as to set a temperature of the substrate to be poled to a first temperature not lower than a Curie temperature (preferably not lower than a temperature higher than the Curie temperature by 50° C.), and to form a plasma at a position facing the substrate to be poled and apply a poling treatment to the substrate to be poled.

One aspect of the present invention is a plasma poling device, comprising:

a poling chamber;

a holding electrode which is disposed in the poling chamber and holds a substrate to be poled;

an opposite electrode which is disposed in the poling chamber and disposed facing the substrate to be poled held on the holding electrode;

a first power source and a ground potential connected to the holding electrode via a first switch;

a second power source and the ground potential connected to the opposite electrode via a second switch;

a gas supply mechanism supplying a plasma forming gas to a space between the opposite electrode and the holding electrode;

a temperature control mechanism controlling a temperature of the substrate to be poled held on the holding electrode; and

a control unit controlling the first power source, the second power source, the gas supply mechanism, and the temperature control mechanism, wherein

the first switch switches from a first state in which the holding electrode and the first power source are electrically connected to each other, to a second state in which the holding electrode and the ground potential are electrically connected to each other,

the second switch switches from a third state in which the opposite electrode and the ground potential are electrically connected to each other, to a fourth state in which the opposite electrode and the second power source are electrically connected to each other, and

the control unit controls the first power source, the second power source, the gas supply mechanism, and the temperature control mechanism so as to set a temperature of the substrate to be poled to a first temperature not lower than a Curie temperature (preferably not lower than a temperature higher than the Curie temperature by 50° C.), and to form a plasma at a position facing the substrate to be poled and apply a poling treatment to the substrate to be poled, in the first state and the third state or in the second state and the fourth state.

Further, in one aspect of the present invention, the control unit is controlled so as to apply the poling treatment to the substrate to be poled, while decreasing a temperature from the first temperature to a second temperature or while increasing the temperature from the second temperature to the first temperature, and

the second temperature is not lower than 50° C. and also lower than the first temperature.

One aspect of the present invention is a plasma poling device, comprising:

a poling chamber;

a holding electrode which is disposed in the poling chamber and holds a substrate to be poled;

an opposite electrode which is disposed in the poling chamber and disposed facing the substrate to be poled held on the holding electrode;

a power source electrically connected to one electrode of the holding electrode and the opposite electrode;

a gas supply mechanism supplying a plasma forming gas to a space between the opposite electrode and the holding electrode;

a temperature control mechanism controlling a temperature of the substrate to be poled held on the holding electrode; and

a control unit controlling the power source, the gas supply mechanism, and the temperature control mechanism, wherein

the control unit controls the power source, the gas supply mechanism, and the temperature control mechanism so as to set a temperature of the substrate to be poled to a first temperature not lower than 100° C., and to form a plasma at a position facing the substrate to be poled and apply a poling treatment to the substrate to be poled.

One aspect of the present invention is a plasma poling device, comprising:

a poling chamber;

a holding electrode which is disposed in the poling chamber and holds a substrate to be poled;

an opposite electrode which is disposed in the poling chamber and disposed facing the substrate to be poled held on the holding electrode;

a first power source and a ground potential connected to the holding electrode via a first switch;

a second power source and the ground potential connected to the opposite electrode via a second switch;

a gas supply mechanism supplying a plasma forming gas to a space between the opposite electrode and the holding electrode;

a temperature control mechanism controlling a temperature of the substrate to be poled held on the holding electrode; and

a control unit controlling the first power source, the second power source, the gas supply mechanism, and the temperature control mechanism, wherein

the first switch switches from a first state in which the holding electrode and the first power source are electrically connected to each other, to a second state in which the holding electrode and the ground potential are electrically connected to each other,

the second switch switches from a third state in which the opposite electrode and the ground potential are electrically connected to each other, to a fourth state in which the opposite electrode and the second power source are electrically connected to each other, and

the control unit controls the first power source, the second power source, the gas supply mechanism, and the temperature control mechanism so as to set a temperature of the substrate to be poled to a first temperature not lower than 100° C., and to form a plasma at a position facing the substrate to be poled and apply a poling treatment to the substrate to be poled, in the first state and the third state or in the second state and the fourth state.

Further, in one aspect of the present invention, the control unit is controlled so as to apply the poling treatment to the substrate to be poled, while decreasing a temperature from the first temperature to a second temperature or while increasing the temperature from the second temperature to the first temperature, and

the second temperature is not lower than 100° C. and also lower than the first temperature.

In one aspect of the present invention, the substrate to be poled is the one in which a piezoelectric material film is formed on a silicon wafer having a thickness smaller than a thickness of the SEMI standard or a silicon wafer having a thickness not larger than 400 μm.

In one aspect of the present invention, the substrate to be poled is the one in which a piezoelectric material film is formed on any substrate of a metal substrate, a metal substrate having an oxidation resistance, a metal substrate having a heat resistance against the Curie temperature of the substrate to be poled or the temperature at which the residual polarization value in the hysteresis curve of the substrate to be poled becomes 0%, an iron based substrate (preferably a substrate such as an iron based alloy, a stainless series, and a SUS), and an Ni based substrate (e.g., a substrate such as an Ni alloy).

In one aspect of the present invention, the substrate to be poled is the one in which a piezoelectric material film is formed on any substrate of a glass substrate, a glass substrate having an oxidation resistance, and a glass substrate having a heat resistance against the Curie temperature of the substrate to be poled or the temperature at which the residual polarization value in the hysteresis curve of the substrate to be poled becomes 0%.

In one aspect of the present invention, preferably the substrate to be poled is a substrate including a dielectric body or an insulating body.

In one aspect of the present invention, preferably the substrate to be poled is a substrate including a piezoelectric body.

In one aspect of the present invention, preferably the substrate to be poled is a substrate including a pyroelectric body.

In one aspect of the present invention, preferably the substrate to be poled is a substrate including a ferroelectric body.

In one aspect of the present invention, a DC voltage for forming a DC plasma or a DC voltage component for forming a high frequency plasma when power is supplied to one electrode of the holding electrode and the opposite electrode, is ±50 V to ±2 kV.

In one aspect of the present invention, any of the above-described plasma poling devices comprises a pressure control mechanism controlling a pressure inside the poling chamber to 0.01 Pa to an air pressure when the poling treatment is performed.

In one aspect of the present invention, the plasma forming gas is one or more kinds of gas selected from a group of inert gas, H₂, N₂, O₂, F₂, CₓH_{y}, CₓF_{y}, and air.

One aspect of the present invention is a piezoelectric body, wherein

a poling treatment is applied to the substrate to be poled by any of the above-described plasma poling devices, and the substrate to be poled is provided with piezoelectric activity.

One aspect of the present invention is a film forming device, comprising

any of the above-described plasma poling devices.

Further, in one aspect of the present invention, the film forming device is any one of a spin coating device, a lamp annealing device, a sputtering device, a CVD device, and an evaporation device.

One aspect of the present invention is an etching device, comprising

any of the above-described plasma poling devices.

One aspect of the present invention is a lamp annealing device, comprising:

a chamber;

a holding electrode which is disposed in the chamber and holds a substrate to be poled including any film of a dielectric material film, an insulating material film, a piezoelectric material film, a pyroelectric material film, and a ferroelectric material film;

an opposite electrode which is disposed in the chamber and disposed facing the substrate to be poled held on the holding electrode;

a lamp heater irradiating the substrate to be poled with lamp light;

a power source electrically connected to one electrode of the holding electrode and the opposite electrode;

a gas supply mechanism supplying a plasma forming gas to a space between the opposite electrode and the holding electrode; and

a control unit controlling the lamp heater, the power source, and the gas supply mechanism.

Further, in one aspect of the present invention, the control unit controls the lamp heater, the power source, and the gas supply mechanism, so that the substrate to be poled is heated to a crystallization temperature and any of the films is crystallized by the irradiation of the lamp light from the lamp heater, and so that a plasma is formed at a position facing the substrate to be poled and a poling treatment is applied to the substrate to be poled at a first temperature lower than the crystallization temperature and also not lower than a temperature at which a residual polarization value in a hysteresis curve of the substrate to be poled becomes 0%.

In one aspect of the present invention, the control unit controls the lamp heater, the power source, and the gas supply mechanism, so that the substrate to be poled is heated to a crystallization temperature and any of the films is crystallized by the irradiation of the lamp light from the lamp heater, and so that a plasma is formed at a position facing the substrate to be poled and a poling treatment is applied to the substrate to be poled at a first temperature lower than the crystallization temperature and also not lower than a Curie temperature (preferably not lower than a temperature higher than the Curie temperature by 50° C.).

In one aspect of the present invention, the control unit controls the lamp heater, the power source, and the gas supply mechanism, so that the substrate to be poled is heated to a crystallization temperature and any of the films is crystallized by the irradiation of the lamp light from the lamp heater, and so that a plasma is formed at a position facing the substrate to be poled and a poling treatment is applied to the substrate to be poled at a first temperature lower than the crystallization temperature and also not lower than 100° C.

In one aspect of the present invention, the control unit controls the lamp heater, the power source, and the gas supply mechanism, so that a plasma is formed at a position facing the substrate to be poled while the substrate to be poled is heated to a crystallization temperature by the irradiation of the lamp light from the lamp heater, and thereby a poling treatment is applied to the substrate to be poled while any of the films is crystallized.

One aspect of the present invention is a lamp annealing device, comprising:

a chamber;

a holding electrode which is disposed in the chamber and holds a substrate to be poled including any film of a dielectric material film, an insulating material film, a piezoelectric material film, a pyroelectric material film, and a ferroelectric material film;

an opposite electrode which is disposed in the chamber and disposed facing the substrate to be poled held on the holding electrode;

a lamp heater irradiating the substrate to be poled with lamp light;

a first power source and a ground potential connected to the holding electrode via a first switch;

a second power source and the ground potential connected to the opposite electrode via a second switch;

a gas supply mechanism supplying a plasma forming gas to a space between the opposite electrode and the holding electrode; and

a control unit controlling the lamp heater, the first power source, the second power source, and the gas supply mechanism, wherein

the first switch switches from a first state in which the holding electrode and the first power source are electrically connected to each other, to a second state in which the holding electrode and the ground potential are electrically connected to each other,

the second switch switches from a third state in which the opposite electrode and the ground potential are electrically connected to each other, to a fourth state in which the opposite electrode and the second power source are electrically connected to each other.

Further, in one aspect of the present invention, the control unit controls the lamp heater, the first power source, the second power source and the gas supply mechanism, so that the substrate to be poled is heated to a crystallization temperature and any of the films is crystallized by the irradiation of the lamp light from the lamp heater, and so that a plasma is formed at a position facing the substrate to be poled in the first state and the third state or in the second state and the fourth state and a poling treatment is applied to the substrate to be poled at a first temperature lower than the crystallization temperature and also not lower than a temperature at which a residual polarization value in a hysteresis curve of the substrate to be poled becomes 0%.

In one aspect of the present invention, the control unit controls the lamp heater, the first power source, the second power source and the gas supply mechanism, so that the substrate to be poled is heated to a crystallization temperature and any of the films is crystallized by the irradiation of the lamp light from the lamp heater, and so that a plasma is formed at a position facing the substrate to be poled in the first state and the third state or in the second state and the fourth state and a poling treatment is applied to the substrate to be poled at a first temperature lower than the crystallization temperature and also not lower than a Curie temperature (preferably not lower than a temperature higher than the Curie temperature by 50° C.).

In one aspect of the present invention, the control unit controls the lamp heater, the first power source, the second power source, and the gas supply mechanism, so that the substrate to be poled is heated to a crystallization temperature and any of the films is crystallized by the irradiation of the lamp light from the lamp heater, and so that a plasma is formed at a position facing the substrate to be poled in the first state and the third state or in the second state and the fourth state and a poling treatment is applied to the substrate to be poled at a first temperature lower than the crystallization temperature and also not lower than 100° C.

In one aspect of the present invention, the control unit controls the lamp heater, the first power source, the second power source, and the gas supply mechanism, so that a plasma is formed at a position facing the substrate to be poled in the first state and the third state or in the second state and the fourth state while the substrate to be poled is heated to a crystallization temperature by the irradiation of the lamp light from the lamp heater, and thereby a poling treatment is applied to the substrate to be poled while any of the films is crystallized.

In one aspect of the present invention, the control unit is controlled so as to apply the poling treatment to the substrate to be poled while decreasing a temperature from the first temperature to a second temperature, and

the second temperature is not lower than a temperature at which a residual polarization value becomes 50% of a residual polarization value at a room temperature in the hysteresis curve of the substrate to be poled, and also lower than the first temperature.

In one aspect of the present invention, the control unit is controlled so as to apply the poling treatment to the substrate to be poled while decreasing a temperature from the first temperature to a second temperature, and

the second temperature is not lower than 50° C. and also lower than the first temperature.

In one aspect of the present invention, the control unit is controlled so as to apply the poling treatment to the substrate to be poled while decreasing a temperature from the first temperature to a second temperature, and

the second temperature is not lower than 100° C. and also lower than the first temperature.

In one aspect of the present invention, the substrate to be poled is the one in which any of the films is formed on a silicon wafer having a thickness smaller than a thickness of the SEMI standard or a silicon wafer having a thickness not larger than 400 μm.

In one aspect of the present invention, the substrate to be poled is the one in which any of the films is formed on any substrate of a metal substrate, a metal substrate having an oxidation resistance, a metal substrate having a heat resistance against the Curie temperature of the substrate to be poled or the temperature at which the residual polarization value in the hysteresis curve of the substrate to be poled becomes 0%, an iron based substrate (preferably a substrate such as an iron based alloy, a stainless series, and a SUS), and an Ni based substrate (e.g., a substrate such as an Ni alloy).

In one aspect of the present invention, the substrate to be poled is the one in which any of the films is formed on any substrate of a glass substrate, a glass substrate having an oxidation resistance, and a glass substrate having a heat resistance against the Curie temperature of the substrate to be poled or the temperature at which the residual polarization value in the hysteresis curve of the substrate to be poled becomes 0%.

In one aspect of the present invention, a DC voltage for forming a DC plasma or a DC voltage component for forming a high frequency plasma when power is supplied to one electrode of the holding electrode and the opposite electrode, is ±50 V to ±2 kV.

In one aspect of the present invention, any of the above-described lamp annealing devices comprises a pressure control mechanism controlling a pressure inside the chamber to 0.01 Pa to an air pressure when the poling treatment is performed.

In one aspect of the present invention, the plasma forming gas is one or more kinds of gas selected from a group of inert gas, H₂, N₂, O₂, F₂, CₓH_{y}, CₓF_{y}, and air.

In one aspect of the present invention, any of the above-described lamp annealing devices further comprises a pressure mechanism pressuring an inside of the chamber.

In one aspect of the present invention, the pressure mechanism includes a gas introduction mechanism introducing pressurized gas into the chamber, and a gas exhaustion mechanism exhausting the gas in the chamber.

One aspect of the present invention is a manufacturing method of a piezoelectric body for manufacturing a piezoelectric body by applying a poling treatment to a piezoelectric material object at a first temperature, wherein

the first temperature is not lower than a temperature at which a residual polarization value in a hysteresis curve of the piezoelectric material object becomes 0%.

Further, in one aspect of the present invention, the poling treatment is applied to the piezoelectric material object while a temperature is decreased from the first temperature to a second temperature or while the temperature is increased from the second temperature to the first temperature, and

the second temperature is not lower than a temperature at which a residual polarization value becomes 50% of a residual polarization value at a room temperature in the hysteresis curve of the piezoelectric material object, and also lower than the first temperature.

One aspect of the present invention is a manufacturing method of a piezoelectric body for manufacturing a piezoelectric body by applying a poling treatment to a piezoelectric material object at a first temperature, wherein

the first temperature is not lower than a Curie temperature (preferably not lower than a temperature higher than the Curie temperature by 50° C.).

Further, in one aspect of the present invention, the poling treatment is applied to the piezoelectric material object while a temperature is decreased from the first temperature to a second temperature, or while the temperature is increased from the second temperature to the first temperature, and

the second temperature is not lower than 50° C. and also lower than the first temperature.

One aspect of the present invention is a manufacturing method of a piezoelectric body for manufacturing a piezoelectric body by applying a poling treatment to a piezoelectric material object at a first temperature, wherein

the first temperature is not lower than 100° C.

Further, in one aspect of the present invention, the poling treatment is applied to the piezoelectric material object while a temperature is decreased from the first temperature to a second temperature, or while the temperature is increased from the second temperature to the first temperature, and

the second temperature is not lower than 100° C. and also lower than the first temperature.

In one aspect of the present invention, the piezoelectric material object is the one in which a piezoelectric material film is formed on a substrate, and

the poling treatment is performed by forming a plasma at a position facing the piezoelectric material film.

In one aspect of the present invention, a rear surface of the substrate is polished and a thickness of the substrate is reduced before the piezoelectric material film is formed on the substrate.

One aspect of the present invention is a manufacturing method of a piezoelectric body, wherein

a rear surface of a substrate is polished and a thickness of the substrate is reduced,

a piezoelectric material film is formed on the substrate, and

a poling treatment is applied to the piezoelectric material film by forming a plasma at a position facing the piezoelectric material film.

In one aspect of the present invention, the thickness of the substrate is not larger than 400 μm after the thickness of the substrate has been reduced.

One aspect of the present invention is any of the above-described manufacturing methods of a piezoelectric body, which is a manufacturing method of a piezoelectric body for performing the poling treatment using a plasma poling device, wherein

the plasma poling device includes:

a poling chamber;

a holding electrode which is disposed in the poling chamber and holds the substrate;

an opposite electrode which is disposed in the poling chamber and disposed facing the substrate held on the holding electrode;

a power source electrically connected to one electrode of the holding electrode and the opposite electrode;

a gas supply mechanism supplying a plasma forming gas to a space between the opposite electrode and the holding electrode; and

a temperature control mechanism controlling a temperature of the substrate held on the holding electrode.

One aspect of the present invention is any of the above-described manufacturing methods of a piezoelectric body, which is a manufacturing method of a piezoelectric body for performing the poling treatment using a plasma poling device, wherein

the plasma poling device includes:

a poling chamber;

a holding electrode which is disposed in the poling chamber and holds the substrate;

an opposite electrode which is disposed in the poling chamber and disposed facing the substrate held on the holding electrode;

a first power source and a ground potential connected to the holding electrode via a first switch;

a second power source and the ground potential connected to the opposite electrode via a second switch;

a gas supply mechanism supplying a plasma forming gas to a space between the opposite electrode and the holding electrode; and

a temperature control mechanism controlling a temperature of the substrate held on the holding electrode.

One aspect of the present invention is a manufacturing method of a piezoelectric body, comprising the steps of:

forming a piezoelectric material film on a substrate;

irradiating the piezoelectric material film with lamp light from a lamp heater, thereby heating the piezoelectric material film to a crystallization temperature to crystallize the film; and

forming a plasma at a position facing the piezoelectric material film and applying a poling treatment to the piezoelectric material film at a first temperature, wherein

the first temperature is lower than the crystallization temperature and also not lower than a temperature at which a residual polarization value in a hysteresis curve of the piezoelectric material film becomes 0%.

Further, in one aspect of the present invention, the poling treatment is applied to the piezoelectric material film while a temperature is decreased from the first temperature to a second temperature, and

the second temperature is not lower than a temperature at which a residual polarization value becomes 50% of a residual polarization value at a room temperature in the hysteresis curve of the piezoelectric material film, and also lower than the first temperature.

One aspect of the present invention is a manufacturing method of a piezoelectric body, comprising the steps of:

forming a piezoelectric material film on a substrate;

irradiating the piezoelectric material film with lamp light from a lamp heater, thereby heating the piezoelectric material film to a crystallization temperature to crystallize the film; and

forming a plasma at a position facing the piezoelectric material film and applying a poling treatment to the piezoelectric material film at a first temperature, wherein

the first temperature is lower than the crystallization temperature and also not lower than a Curie temperature (preferably not lower than a temperature higher than the Curie temperature by 50° C.).

Further, in one aspect of the present invention, the poling treatment is applied to the piezoelectric material film while a temperature is decreased from the first temperature to a second temperature, and

the second temperature is not lower than 50° C. and also lower than the first temperature.

One aspect of the present invention is a manufacturing method of a piezoelectric body, comprising the steps of:

forming a piezoelectric material film on a substrate;

irradiating the piezoelectric material film with lamp light from a lamp heater, thereby heating the piezoelectric material film to a crystallization temperature to crystallize the film; and

forming a plasma at a position facing the piezoelectric material film and applying a poling treatment to the piezoelectric material film at a first temperature, wherein

the first temperature is lower than the crystallization temperature and also not lower than 100° C.

Further, in one aspect of the present invention, the poling treatment is applied to the piezoelectric material film while a temperature is decreased from the first temperature to a second temperature, and

the second temperature in not lower than 100° C. and also lower than the first temperature.

One aspect of the present invention is a manufacturing method of a piezoelectric body, comprising the steps of:

forming a piezoelectric material film on a substrate; and

forming a plasma at a position facing the piezoelectric material film while heating the piezoelectric material film to a crystallization temperature by irradiating the piezoelectric material film with lamp light from a lamp heater, and thereby applying a poling treatment to the piezoelectric material film while crystallizing the piezoelectric material film.

Further, in one aspect of the present invention, the poling treatment is applied to the piezoelectric material film while a temperature is decreased from the first temperature to a second temperature, and

the second temperature is a temperature not lower than a temperature at which a residual polarization value becomes 50% of a residual polarization value at a room temperature in a hysteresis curve of the piezoelectric material film, or a temperature not lower than 50° C. and also lower than the crystallization temperature.

### Effect of the Invention

One aspect of the present invention can provide any of a poling treatment method capable of performing poling treatment simply by a dry method, a plasma poling device, a piezoelectric body and a manufacturing method thereof, a film forming device and etching device, and a lamp annealing device.

Further, one aspect of the present invention can improve characteristics of a piezoelectric body or the like to which the poling treatment has been applied in either a dry method or a wet method.

### BRIEF DESCRIPTION OF THE DRAWINGS

FIG. 1 is a cross-sectional view schematically showing a plasma poling device according to one aspect of the present invention.

FIG. 2 is a schematic diagram for explaining a reason why poling treatment is performed by heating to a temperature higher than a Curie temperature by 50° C.

FIG. 3 is a diagram for explaining a reason why poling treatment is performed by heating to a temperature not lower than a temperature at which the residual polarization value Pr of a hysteresis curve becomes 0%.

FIG. 4 is a schematic diagram showing a unimorph vibrator.

FIG. 5 is a diagram for explaining a reason why poling becomes easy even for a thick substrate when poling treatment is applied to a piezoelectric material film at a temperature not lower than 250° C.

FIG. 6 is a cross-sectional view schematically showing a plasma poling device according to one aspect of the present invention.

FIG. 7 is a plan view schematically showing a film forming device according to one aspect of the present invention.

FIG. 8 is a plan view schematically showing a film forming device according to one aspect of the present invention.

FIG. 9 is a cross-sectional view showing a state of performing sputter film formation in a sputtering device according to one aspect of the present invention.

FIG. 10 is a cross-sectional view showing a state of performing poling treatment in the sputtering device shown in FIG. 9.

FIG. 11 is a cross-sectional view showing a state of performing sputter film formation and poling treatment at the same time in a sputtering device according to one aspect of the present invention.

FIG. 12 is a cross-sectional view showing a state of performing CVD film formation in a plasma CVD device according to one aspect of the present invention.

FIG. 13 is a cross-sectional view showing a state of performing poling treatment in the plasma CVD device shown in FIG. 12.

FIG. 14 is a cross-sectional view showing a state of performing CVD film formation and poling treatment at the same time in a plasma CVD device according to one aspect of the present invention.

FIG. 15 is a cross-sectional view showing a state of performing evaporation film formation in an evaporation device according to one aspect of the present invention. This evaporation device includes a plasma poling device.

FIG. 16 is a cross-sectional view showing a state of performing poling treatment in the evaporation device shown in FIG. 15.

FIG. 17 is a cross-sectional view showing a state of performing evaporation film formation and poling treatment at the same time in an evaporation device according to one aspect of the present invention.

FIG. 18 is a cross-sectional view schematically showing a pressure-type lamp annealing device according to one aspect of the present invention.

FIG. 19 is a schematic diagram showing a conventional poling device.

### BEST MODE FOR CARRYING OUT THE INVENTION

Hereinafter, embodiments of the present invention will be explained in detail by the use of the drawings. Note that it is easily understood by those skilled in the art that the present invention is not limited to the following explanation and the modes and details of the present invention can be changed without departing from the gist and the scope thereof. Accordingly, the present invention is not to be construed, limited to the following description of the embodiments.

### First Embodiment

### Plasma Poling Device

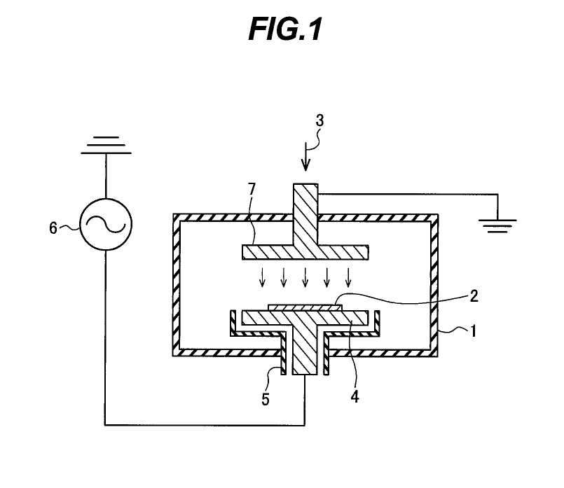

FIG. 1 is a cross-sectional view schematically showing a plasma poling device according to one aspect of the present invention. This plasma poling device is a device for performing poling treatment.

The plasma poling device includes a poling chamber 1, and a holding electrode 4 for holing a substrate to be poled 2 is disposed in the lower part in the poling chamber 1. While the details of the substrate to be poled 2 will be described below, the substrate to be poled 2 is a substrate including a ferroelectric body, or a substrate in which a ferroelectric body is formed on a substrate, or the like, for example, and substrates having various shapes can be used.

The holding electrode 4 is electrically connected to a high frequency power source 6 and the holding electrode 4 functions also as an RF applying electrode. The circumference and the lower part of the holding electrode 4 are shielded by an earth shield 5. Note that, while the high frequency power source 6 is used in the present embodiment, another power source such as a DC power source and a microwave power source, for example, may be used.

In the upper part in the poling chamber 1, a gas shower electrode (opposite electrode) 7 is disposed at a position facing the holding electrode 4 in parallel. These are a pair of parallel plate type electrodes. The gas shower electrode is connected to the ground potential. Note that, while the holding electrode 4 is connected with the power source and the gas shower electrode is connected with the ground potential in the present embodiment, the holding electrode 4 may be connected with the ground potential and the gas shower electrode may be connected with the power source.

On the lower surface of the gas shower electrode 7, plural supply ports (not shown in the drawing) are formed for supplying a plasma forming gas in a shower state onto the surface side of the substrate to be poled 2 (space between the gas shower electrode 7 and the holding electrode 4). As the plasma forming gas, Ar, He, N₂, O₂, F₂, CₓF_{y}, air, or the like can be used, for example.

A gas introduction path (not shown in the drawing) is provided inside the gas shower electrode 7. One side of this gas introduction path is connected to the above supply ports, and the other side of the gas introduction path is connected to a plasma forming gas supply mechanism 3. Further, an exhaustion port is provided for the poling chamber 1 for exhausting the inside of the poling chamber 1 into vacuum. This exhaustion port is connected to an exhaustion pump (not shown in the drawing).

Further, the plasma poling device includes a control unit (not shown in the drawing) controlling the high frequency power source 6, the plasma forming gas supply mechanism 3, the exhaustion pump, and the like, and this control unit is configured to control the plasma poling device so as to perform the poling treatment as will be described below.

Further, preferably the plasma poling device includes a temperature control mechanism controlling a temperature of the substrate to be poled 2 to various temperatures in the poling treatment.

<Poling Treatment Method>

Next, there will be explained a method of applying the poling treatment to the substrate to be poled by the use of the above plasma poling device. Here, the poling treatment method according to one aspect of the present invention not only indicates so-called poling treatment by a high electric field (i.e., polarization process of providing piezoelectric activity for a ferroelectric body by applying a high DC electric field to a piece of ceramic provided with electrodes), but also includes thermal poling. In particular, this thermal poling can cause a dielectric body preliminarily to have anisotropy, by applying DC voltage or high frequency voltage and shutting down the DC voltage or the high frequency voltage while heating the dielectric body. Ions inside the dielectric body are caused to move easily by the provided thermal energy, and ion movement and polarization are induced by the voltage applied there, and resultantly the whole substrate is poled easily.

Note that, when the thermal poling treatment is performed, it is necessary to add a heating mechanism to the above plasma poling device and to heat the substrate to be poled by this heating mechanism.

[1] Substrate to be Poled

First, the substrate to be poled 2 is prepared. The substrate to be poled 2 is a substrate including at least one of substrates to which the poling treatment is applied, such as a dielectric body, insulating body, a piezoelectric body, a pyroelectric body, and a ferroelectric body, for example, and also various substrates to be poled can be used, since this poling treatment is effective for all the inorganic materials and organic materials which have super conductivity, dielectricity, piezoelectricity, pyroelectricity, ferroelectricity, and nonlinear optical property.

Specific examples of a material applicable to the substrate to be poled 2 are as follows.

TiO₂, MgTiO₃—CaTiO₃ series, BaTiO₃ series, CaSnO₃, SrTiO₃, PbTiO₃, CaTiO₃, MgTiO₃, SrTiO₃, CaTiO₃ series:BaTiO₃ series, BaO-R₂O₃-nTiO₂ series (R=Nd, Sm . . . , n=4, 5, . . . ), Al₂O₃, diamond series (diamond-like carbon, etc.), BN, SiC, BeO, AlN, BaTi₅O₁₁, Ba₂Ti₉O₂₀, tungsten bronze AₓBo₃: Ba₂NaNb₅O₁₅ (BNN), Ba₂NaTa₅O₁₅ (BNT), Sr₂NaNb₅O₁₅ (SNN), K₃Li₂Nb₅O₁₅ (KLN), K₂BiNb₅O₁₅ (KBN), perovskite series, (K, Na, Li) (Nb, Ta, Sb)O₃, BiₓNa₁₋ₓTiO₃ (BNT), BiₓK₁₋ₓTiO₃ (BKT), BiFeO₃, SrBi₂Ta₂O₉ (SBT), Bi₄Ti₃O₁₂, Bi₄₋ₓLaₓTi₃O₁₂ (BLT), SrBi₂Nb₂O₉ (SBN), Bi₂WO₄ (BWO), SiO₂, LiNbO₃, LiTaO₃, Sr_{0.5}Ba_{0.5}Nb₂O₆, KDP (KH₂PO₄) C₄H₄O₆NaK.4H₂O, NaNO₂, (NH₂)₂CS, K₂SeO₄, PbZrO₃, (NH₂)₂CS, (NH₄) SO₄, NaNbO₃, BaTiO₃, PbTiO₃, SrTiO₃, KNbO₃, NaNbO₃, BiFeO₃, (Na, La) (Mg, W)O₃, La_{1/3}NbO₃, La_{1/3}TaO₃, Ba₃MgTa₂O₉, Sr₄NaSb₃O₁₂, A₂BRO₆ (A: alkali earths, B: Fe, Ln, R: Mo, Mn, W, Ru; atomic valence difference between B and R≧2), Bi₂NiMnO₆, Sr₂FeMoO₆, BaLnMn₂O₆, NaₓWO₃, Ln_{1/3}NbO₃, Ba₂In₂O₅, Sr₂Fe₂O₅, Sr₂Nd₂O₇, Sr₂Ta₂O₇, La₂Ti₂O₇, MgSiO₃, CaIrO₃, CuNMn₃, GaNMn₃, ZnNMn₃, CuNMn₃, Ca₂MnO₄, FeTiO₃, LiNbO₃, LiTaO₃, Gd₂ (MoO₄)₃, SrTiO₃, KTaO₃, RFe₂O₄, La₂₋ₓSrₓCuO₄, Me₃B₇O₁₃X (ion radius of Me: 0.97 Å (Cd²⁺) to 0.66 Å (Mg²⁺), X: halogen), Ni₃B₇O₁₃1, BiFeO₃, BiMnO₃, Pb₂ (Co_{1/2}W_{1/2})O₃, Pb(Fe_{1/2}Nb_{1/2})O₃, A₂BRO₆ (A: alkali earths, B: Fe, Ln, R: Mo, Mn, W, Ru, atomic valence difference between B and R≧2), Bi₂NiMnO₆, YMnO₃, YbMnO₃, HoMnO₃, BaMnF₄, BaFeF₄, BaNiF₄, BaCoF₄, YFe₂O₄, LuFe₂O₄, TbMnO₃, DyMnO₃, Ba₂Mg₂Fe₁₂O₂₂, CuFeO₂, Ni₃V₂O₈, LiCu₂O₂, LiV₂O₄, LiCr₂O₄, NaV₂O₄, NaCr₂O₄, CoCr₂O₄, LiFeSi₂O₆, NaCrSi₂O₆, LiFeSi₂O₆, NaCrSi₂O₆, MnWO₄, TbMn₂O₅, DyMn₂O₅, HoMn₂O₅, YMn₂O₅, R=Tb, Dy, Ho, Y, RbFe(MoO₄)₂, Pr₃Ga₅SiO₁₄, Nd₃Ga₅SiO₁₄, Nd₃Ga₅SiO₁₄, A₃BFe₃Si₂O₁₄ (A=Ba, Sr, Ca, B=Nb), T various kinds of pyrochlore oxide, crystal (SiO₂), LiNbO₃, BaTiO₃, PbTiO₃ (PT), Pb(Zr, Ti)O₃ (PZT), Pb(Zr,Ti,Nb)O₃ (PZTN), PbNb₂O₆, PVF₂, PMN-PZT, lead magnesium niobate-PZT series >Pb(Mg_{1/3}Nb_{2/3})O₃ (PMN)—PZT, Pb(Ni_{1/3}Nb_{2/3})O₃ (PNN)—PZT, Pb(Mg_{1/3}Nb_{2/3})O₃ (PMN)—PT, Pb(Ni_{1/3}Nb_{2/3})O₃ (PNN)—PT, Pb(Mg_{1/3}Nb_{2/3})O₃—PbTiO₃ (PMN-PT), BaTiO₃, (Sr₁₋ₓ, Baₓ)TiO₃, (Pb_{1-y}, Ba_{y}) (Zr₁₋ₓ, Tix)O₃ (x=0 to 1, y=0 to 1), CdTiO₃, HgTiO₃, CaTiO₃, GdFeO₃, SrTiO₃, PbTiO₃, BaTiO₃, PbTiO₃, PbZrO₃, Bi_{0.5}Na_{0.5}TiO₃, Bi_{0.5}K_{0.5}TiO₃, KNbO₃, LaAlO₃, FeTiO₃, MgTiO₃, CoTiO₃, NiTiO₃, CdTiO₃, (K₁₋ₓNaₓ)NbO₃, K(Nb₁₋ₓTaₓ)O₃, (K₁₋ₓNaₓ) (Nb_{1-y}Ta_{y})O₃, KNbO₃, RbNbO₃, TlNbO₃, CsNbO₃, AgNbO₃, Pb(Ni_{1/3}Nb_{2/3})O₃, Ba(Ni_{1/3}Nb_{2/3})O₃, (Li_{1/2}Bi_{1/2}) TiO₃, Bi(Mg_{1/2}Ti_{1/2})O₃, Bi(Zn_{1/2}Ti_{1/2})O₃, Bi(Ni_{1/2}Ti_{1/2})O₃, (Bi, La) (Mg_{1/2}Ti_{1/2})O₃, (A¹⁺_{1/2}A³⁺_{1/2}) (B²⁺_{1/3}B⁵⁺_{2/3})O₃ (Here, into A and B, substituted are elements such as A¹⁺=Li, Na, K, Ag, A²⁺=Pb, Ba, Sr, Ca, A³⁺=Bi, La, Ce, Nd, B¹⁺=Li, Cu, B²⁺=Mg, Ni, Zn, Co, Sn, Fe, Cd, Cu, Cr, B³⁺=Mn, Sb, Al, Yb, In, Fe, Co, Sc, Y, Sn, B⁴⁺=Ti, Zr, B⁵⁺=Nb, Sb, Ta, Bi, B⁶⁺=W, Te, Re), Pb(Mg_{1/3}Nb_{2/3})O₃ (PMN), Pb(Mg_{1/3}Ta_{2/3})O₃ (PMTa), Pb(Mg_{1/2}W_{1/2})O₃ (PMW) Pb(Ni_{1/3}Nb_{2/3})O₃ (PNN), Pb(Ni_{1/3}Ta_{2/3})O₃ (PNTa), Pb(Ni_{1/2}W_{1/2})O₃ (PNW), Pb(Zn_{1/3}Nb_{2/3})O₃ (PZN), Pb(Zn_{1/3}Ta_{2/3})O₃ (PZTa) Pb(Zn_{1/2}W_{1/2})O₃ (PZW), Pb(Sc_{1/2}Nb_{1/2})O₃ (PScN), Pb(Sc_{1/2}Ta_{1/2})O₃ (PScTa), Pb(Cd_{1/3}Nb_{2/3})O₃ (PCdN), Pb(Cd_{1/3}Ta_{2/3})O₃ (PCdT), Pb(Cd_{1/2}W_{1/2})O₃ (PCdW), Pb(Mn_{1/3}Nb_{2/3})O₃ (PMnN), Pb(Mn_{1/3}Ta_{2/3})O₃ (PMnTa), Pb(Mn_{1/2}W_{1/2})O₃ (PMnW), Pb(Co_{1/3}Nb_{2/3})O₃ (PCoN) Pb(Co_{1/3}Ta_{2/3})O₃ (PCoTa), Pb(Co_{1/2}W_{1/2})O₃ (PCoW), Pb(Fe_{1/2}Nb_{1/2})O₃ (PFN), Pb(Fe_{1/2}Ta_{1/2})O₃ (PFTa), Pb(Fe_{1/3}W_{1/3})O₃ (PFW) Pb(Cu_{1/3}Nb_{2/3})O₃ (PCuN), Pb(Yb_{1/2}Nb_{1/2})O₃ (PYbN), Pb(Yb_{1/2}Ta_{1/2})O₃ (PYbTa), Pb(Yb_{1/2}W_{1/2})O₃ (PYbW), Pb(Ho_{1/2}Nb_{1/2})O₃ (PHoN) Pb(Ho_{1/2}Ta_{1/2})O₃ (PHoTa), Pb(Ho_{1/2}W_{1/2})O₃ (PHoW) Pb(In_{1/2}Nb_{1/2})O₃ (PInN), Pb(In_{1/2}Ta_{1/2})O₃ (PInTa), Pb(In_{1/2}W_{1/2})O₃ (PInW) Pb(Lu_{1/2}Nb_{1/2})O₃ (PLuN), Pb(Lu_{1/2}Ta_{1/2})O₃ (PLuTa), Pb(Lu_{1/2}W_{1/2})O₃ (PLuW), Pb(Er_{1/2}Nb_{1/2})O₃ (PErN), Pb(Er_{1/2}Ta_{1/2})O₃ (PErT) Pb(Sb_{1/2}Nb_{1/2})O₃ (PSbN), Pb(Sb_{1/2}Ta_{1/2})O₃ (PSbT), BaZrO₃—BaTiO₃, BaTiO₃—SrTiO₃, Pb(Mg_{1/3}Nb_{2/3})O₃, Pb(Sc_{1/2}Nb_{1/2})O₃, Pb(Mg_{1/3}Nb_{2/3})O₃ (PMN), PMN-PbTiO₃, PMN-PZT, nonlinear optical material (inorganic material), for example, a garnet crystal (YAG, YAO, YSO, GSGG, GGG), a fluoride crystal (YLF, LiSAF, LiCAF), a tungstate crystal (KGW, KYW), a vanadate crystal (YVO₄, GdVO₄, etc.), and other materials such as BBO, CBO, CLBO, YCOB, GdCOB, GdYCOB, KTP, KTA, KDP, and LiNbO₃.

Further, as organic nonlinear optical materials, there are (R)-(+)-2-(α-methylbenzylamino)-5-nitropyridine (molecular formula and weight: C₁₃H₁₃N₃O₂=243.26), (S)-(−)-2-(α-methylbenzylamino)-5-nitropyridine (molecular formula and weight: C₁₃H₁₃N₃O₂=243.26), (S)-(−)-N-(5-nitro-2-pyridyl)alaninol (molecular formula and weight: C₈H₁₁N₃O₃=197.19), (S)-(−)-N-(5-nitro-2-pyridyl)prolinol (molecular formula and weight: C₁₀H₁₃N₃O₃=223.23), (S)—N-(5-nitro-2-pyridyl)phenylalaninol (molecular formula and weight: C₁₄H₁₅N₃O₃=273.29), 1,3-dimethylurea (molecular formula and weight: C₃H₈N₂O=88.11), 2-(N,N-dimethylamino)-5-nitroacetanilide (molecular formula and weight: C₁₀H₁₃N₃O₃=223 0.23), 2-amino-3-nitropyridine (molecular formula and weight: C₅H₅N₃O₂=139.11), 2-amino-5-nitropyridine (molecular formula and weight: C₅H₅N₃O₂=139.11), 2-aminofluorene (molecular formula and weight: C₁₃H₁₁N=181.23), 2-chloro-3,5-dinitropyridine (molecular formula and weight: C₅H₂ClN₃O₄=203.54), 2-chloro-4-nitro-N-methyl aniline (molecular formula and weight: C₇H₇ClN₂O₂=186.60), 2-chloro-4-nitroaniline (molecular formula and weight: C₆H₅ClN₂O₂=172.57), 2-methyl-4-nitroaniline (molecular formula and weight: C₇H₈N₂O₂=152.15), 2-nitroaniline (molecular formula and weight: C₆H₆N₂O₂=138.12), 3-methyl-4-nitroaniline (molecular formula and weight: C₇H₈N₂O₂=152.15) 3-nitroaniline (molecular formula and weight: C₆H₆N₂O₂=138.12), 4-amino-4′-nitrobiphenyl (molecular formula and weight: C₁₂H₁₀N₂O₂=214.22), 4-dimethylamino-4′-nitrobiphenyl (molecular formula and weight: C₁₄H₁₄N₂O₂=242.27), 4-dimethylamino-4′-nitrostilbene (molecular formula and weight: C₁₆H₁₆N₂O₂=268.31), 4-hydroxy-4′-nitrobiphenyl (molecular formula and weight: C₁₂H₉NO₃=215.20), 4-methoxy-4′-nitrobiphenyl (molecular formula and weight: C₁₃H₁₁NO₃=229.23), 4-methoxy-4′-nitrostilbene (molecular formula and weight: C₁₅H₁₃NO₃=255.27), 4-nitro-3-picolineN-oxide (molecular formula and weight: C₆H₆N₂O₃=154.12), 4-nitroaniline (molecular formula and weight: C₆H₆N₂O₂=138.12), 5-nitroindole (molecular formula and weight: C₈H₆N₂O₂=162.15), 5-nitrouracil (molecular formula and weight: C₄H₃N₃O₄=157.08), N-(2,4-dinitrophenyl)-L-alaninemethyl (molecular formula and weight: C₁₀H₁₁N₃O₆=269.21), N-cyanomethyl-N-methyl-4-nitroaniline (molecular formula and weight: C₉H₉N₃O₂=191.19), N-methyl-4-nitro-o-toluidine (molecular formula and weight: C₈H₁₀N₂O₂=166.18), N-methyl-4-nitroaniline (molecular formula and weight: C₇H₈N₂O₂=152.15), and the like, and while these materials may be used as the substrate to be poled 2, the substrate to be poled is not limited to these materials.

Further, the substrate to be poled 2 may be a substrate in which a piezoelectric material film is formed on a silicon wafer having a thickness smaller than that of the SEMI standard and preferably a silicon wafer having a thickness not larger than 500 μm (more preferably not larger than 400 μm, furthermore preferably not larger than 300 μm, and still further more preferably not larger than 250 μm). Here, the SEMI standard means a standard shown in Table 1. Further, as the piezoelectric material film, the above materials applicable to the substrate to be poled 2 can be used.

TABLE 1
(ALLOWABLE RANGE)

| | 2-inch SINGLE | 3-inch SINGLE | 100-mm SINGLE | 125-mm SINGLE |
|---|---|---|---|---|
| | CRYSTAL SILICON | CRYSTAL | CRYSTAL SILICON | CRYSTAL SILICON |
| | WAFER | SILICON WAFER | WAFER | WAFER |
| DIAMETER(in) | 2.000(±0.015) | 3.000(±0.015) | — | — |
| (mm) | 50.80(±0.38) | 76.20(±0.63) | 100.000(±0.50) | 125.000(±0.50) |
| THICKNESS | 0.0110(±0.0010) | 0.0150(±25) | — | — |
| (CENTER POINT) | 279(±25) | 381(±25) | 525(±20) 625(±20) | 625(±20) |
| (in) (μm) | | | | |
| ORIENTATION | 0.625(±0.065) | 0.875(±0.125) | — | — |
| FLAT LENGTH (in) | 15.88(±1.65) | 22.22(±3.17) | 32.5(±2.5) | 42.5(±2.5) |
| (mm) | | | | |
| SECOND | 0.315(±0.065) | 0.440(±0.060) | — | — |
| ORIENTATION | 8.00(±1.65) | 11.18(±1.52) | 18.0(±2.0) | 27.5(±2.5) |
| FLAT LENGTH (in) | | | | |
| (mm) | | | | |

| | 150-mm SINGLE | | |
|---|---|---|---|
| | CRYSTAL SILICON | 200-mm SINGLE CRYSTAL | 300-mm SINGLE CRYSTAL |
| | WAFER | SILICON WAFER | SILICON WAFER |
| DIAMETER | 150.000(±0.20) | 200.000(±0.20) | 300.000(±0.25) |
| (mm) | | | |
| THICKNESS | 675(±20) | 725(±20) | 775(±25) |
| (CENTER POINT) | | | |
| (μm) | | | |
| ORIENTATION | 57.5(±2.5) | NOTCH DEPTH 1.0(0.25, −0.00) | NOTCH DEPTH 1.0(0.25, −0.00) |
| FLAT LENGTH | | ANGLE 90(5, −1) | ANGLE 90(5, −1) |
| (mm) | | ORIENTATION FLAT | |
| | | DIAMETER 195.50(±0.20) | |
| SECOND | 37.5(±2.5) | — | — |
| ORIENTATION | | | |
| FLAT LENGTH | | | |
| (mm) | | | |

Further, the substrate to be poled 2 may be a substrate in which a piezoelectric material film is formed on any substrate of a metal substrate, a metal substrate having an oxidation resistance, a metal substrate having a heat resistance against the Curie temperature of the above substrate to be poled 2 or a temperature at which the residual polarization value Pr of the hysteresis curve becomes 0%, an iron based substrate (preferably a substrate such as an iron based alloy, a stainless series, and a SUS), and an Ni based substrate (e.g., a substrate such as an Ni alloy). Note that the residual polarization value Pr of the hysteresis curve will be described below.

Further, the substrate to be poled 2 may be a substrate in which a piezoelectric material film is formed on any substrate of a glass substrate, a glass substrate having an oxidation resistance, and a glass substrate having a heat resistance against the Curie temperature of the substrate to be poled 2 or a temperature at which the residual polarization value Pr of the hysteresis curve becomes 0%.

The metal substrate has a large thermal expansion coefficient and Young's modulus, and therefore has an advantage that the piezoelectric material film can move easily and the piezoelectric activity can be easily provided for the piezoelectric material film when an electric field is applied to the piezoelectric material film and the poling treatment is performed.

Further, each of the metal substrate and the glass substrate having the oxidation resistance has an advantage that the substrate can resist against an oxygen atmosphere when the crystallization treatment is applied to the piezoelectric material film in the oxygen atmosphere.

Further, each of the metal substrate and the glass substrate having the heat resistance has an advantage that the substrate can resist against a temperature to which the substrate is heated when the poling treatment is performed while heating the substrate.

[2] Poling Treatment

Next, the substrate to be poled 2 is inserted into the poling chamber 1 and the substrate to be poled 2 is held on the holding electrode 4 in this poling chamber 1.

Subsequently, the poling treatment is applied to the substrate to be poled 2.

In detail, the inside of the poling chamber 1 is exhausted into vacuum by the exhaustion pump. Next, the plasma forming gas such as Ar in a shower state is introduced into the poling chamber 1 from the supply ports of the gas shower electrode 7 and supplied onto the surface of the substrate to be poled 2. This supplied plasma forming gas travels between the holding electrode 4 and the earth shield 5 and is exhausted to the outside of the poling chamber 1 by the exhaustion pump. Then, the inside of the poling chamber 1 is set to a plasma forming gas atmosphere by controlling the pressure and plasma forming gas flow rate into predetermined values by means of the balance between a plasma forming gas supply amount and the exhaustion. Further, a high frequency (RF) power of 380 kHz and 13.56 MHz, for example, is applied by the high frequency power source 6 to generate plasma, and thus the poling treatment is applied to the substrate to be poled 2. Preferably, this poling treatment is performed in the following conditions: the pressure is 0.01 Pa to the air pressure; the power source is a DC power source, the high-frequency power source or a microwave power source; the treatment temperature is not lower than the Curie temperature of the substrate to be poled 2 (preferably not lower than a temperature higher than the Curie temperature by 50° C.), not lower than a temperature at which the residual polarization value Pr (μC/cm²) in the hysteresis curve of the substrate to be poled becomes 0%, or not lower than 100° C. (preferably not lower than 150° C. and more preferably not lower than 250° C.); and the DC voltage component in the plasma formation is ±50 V to ±2 kV. Subsequently, after the poling treatment has been performed for a predetermined time, the supply of the plasma forming gas from the supply port of the gas shower electrode 7 is terminated and the poling treatment is finished.

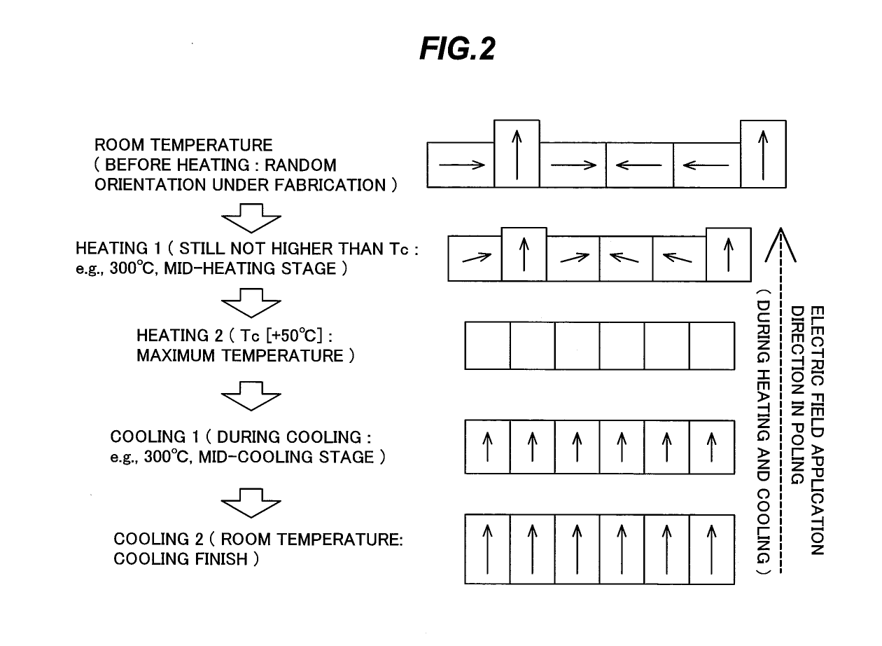

A reason why the poling treatment is performed by the heating to a temperature not lower than the Curie temperature (preferably not lower than a temperature higher than the Curie temperature by 50° C.) will be explained with reference to FIG. 2.

FIG. 2 schematically shows a change in a crystal (polarization axis) orientation when the poling treatment is performed by applying an electric field to the substrate to be poled in the arrow direction, in a cooling process after heating of the substrate to be poled, as the room temperature, heating 1, heating 2, cooling 1 and cooling 2.

As shown in FIG. 2, in the state at the room temperature, a piezoelectric body or the like of the substrate to be poled has a random orientation and the crystal orientation (polarization axis shown by the arrow) is also random.

The state of heating 1 has a temperature not yet higher than the Curie temperature Tc (e.g., 300° C. for PZT) and is a stage during the heating of the substrate to be poled. In this state of heating 1, the crystal (polarization axis) becomes approximately tetragonal compared with the state of the room temperature and has a state of weak spontaneous polarization. Here, the strength of the spontaneous polarization is shown by the length of the arrow. Further, in the state of heating 1, the poling treatment is easily performed compared with the state of the room temperature.

The state of heating 2 is a state in which the substrate to be poled is heated to a temperature higher than the Curie temperature Tc by 50° C. (e.g., approximately 430° C. for PZT). In this state of heating 2, the crystal (polarization axis) becomes tetragonal while changing own orientation and has the state that the spontaneous polarization is lost completely. While this state is generated at the Curie temperature Tc, preferably the temperature is higher than the Curie temperature Tc by 50° C. in order to cause the spontaneous polarization to be lost without fail. By obtaining the state that the spontaneous polarization is lost completely in this manner, it becomes very easy to perform the poling treatment. Therefore, most crystal (polarization axis) orientations are aligned in an electric field application direction by the poling treatment.

The state of cooling 1 is a stage during the cooling of the substrate to be poled at a temperature lower than the Curie temperature Tc (e.g., 300° C. for PZT). When the poling treatment is performed during the cooling from the state of heating 2 to the state of cooling 1, the spontaneous polarization becomes strong in the state that most crystal (polarization axis) orientations are aligned in the electric field application direction.

The state of cooling 2 is a state in which the substrate to be poled is cooled to the room temperature. When the poling treatment is performed during the cooling from the state of cooling 1 to the state of cooling 2, the spontaneous polarization becomes further strongerer than that in the state of cooling 1 in the state that the most crystal (polarization axis) orientations are aligned in the electric field application direction. Accordingly, a piezoelectric body or the like is obtained having a strong spontaneous polarization. Note that the poling treatment may be terminated at a temperature in the state of cooling 2 and, also in this case, a piezoelectric body or the like is obtained having a strong spontaneous polarization.

That is, when the poling treatment is performed by heating the substrate to be poled to the Curie temperature thereof (preferably temperature higher than the Curie temperature by 50° C.), it is possible to improve characteristics of a piezoelectric body or the like compared with the case that the poling treatment is performed at the room temperature.

For example, in the case of PZT, the spontaneous polarization starts to be lost at a temperature of 250° C. to 270° C. and the curie temperature is reached at approximately 380° C. Near the Curie temperature, the PZT crystal lattice is changed into a tetragonal lattice and Ti and Zr within the lattice are moved to stable points, and therefore the spontaneous polarization is lost. By the heating to a temperature higher than the Curie temperature, the crystal lattice is stabilized into the tetragonal lattice and it is possible to remove a specific property of the crystal lattice and to facilitate the poling treatment.

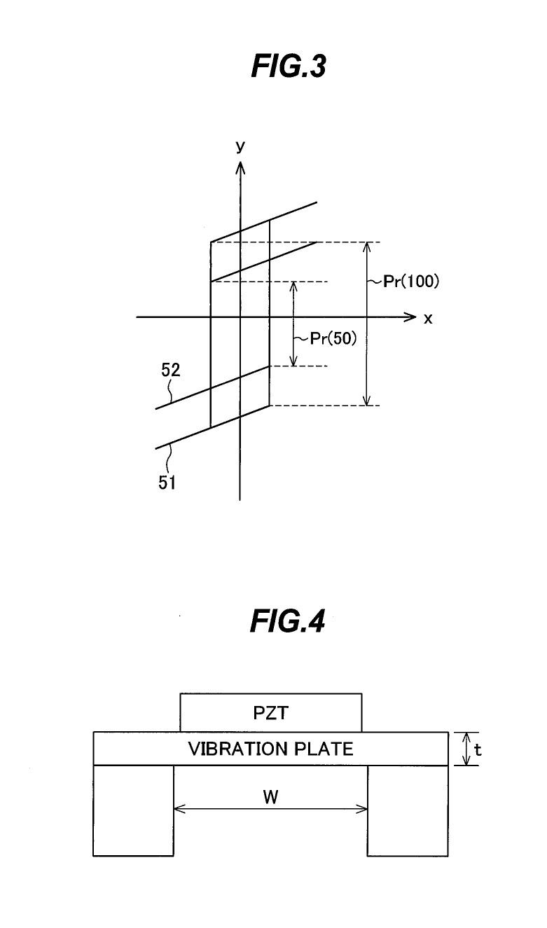

Next, a reason why the poling treatment is performed by the heating to a temperature at which the residual polarization value Pr of the hysteresis curve becomes 0%, will be explained with reference to FIG. 3.

FIG. 3 is a diagram schematically showing a hysteresis curve 51 in which the hysteresis residual polarization value Pr of the substrate to be poled 2 is 100%, and a hysteresis curve 52 in which the hysteresis residual value of the substrate to be poled 2 is 50%. Here, in FIG. 3, the X-axis indicates applied voltage (V) to the substrate to be poled and the Y-axis indicates residual polarization (μC/cm²).

The hysteresis curve 51 shows a result of the hysteresis evaluation for the substrate to be poled 2 at the room temperature, and the residual polarization value Pr (100) of this hysteresis curve 51 is defined to be 100%.

The hysteresis curve 52 shows a result of hysteresis evaluation for the substrate to be poled 2 at a certain temperature, and the residual polarization value Pr (50) of this hysteresis curve 52 is 50% which is a half of the residual polarization value Pr (100). That is, the hysteresis curve 52 shows the result of the hysteresis evaluation for the substrate to be poled 2 at a temperature at which the residual polarization value Pr(50) becomes 50% of the residual polarization value Pr(100).

When the hysteresis evaluation for the substrate to be poled 2 is performed at the Curie temperature, the residual polarization value Pr of the hysteresis curve becomes 0%. That is, the temperature at which the residual polarization value Pr of the hysteresis curve becomes 0% is the Curie temperature.

In the state that the substrate to be poled is heated to the temperature at which the residual polarization value Pr of the hysteresis curve becomes 0%, the crystal (polarization axis) becomes tetragonal while changing own orientation and the spontaneous polarization is lost completely, and therefore it becomes very easy to perform the poling treatment. Therefore, by the poling treatment performed in this state, the orientations of most crystals (polarization axes) are aligned in the electric field application direction.

When the poling treatment is performed while cooling the substrate to be poled to a temperature at which the residual polarization value Pr (50) of the hysteresis curve becomes 500 (e.g., 50° C.), the spontaneous polarization becomes strong in the state that the orientations of the most crystals (polarization axes) are aligned in the electric field application direction. Further, when the poling treatment is performed while cooling the substrate to be poled to the room temperature, the spontaneous polarization becomes further stronger in the state that the orientations of the most crystals (polarization axes) are aligned in the electric field application direction. Accordingly, a piezoelectric body or the like having a strong spontaneous polarization is obtained. Note that the poling treatment may be terminated at a temperature at which the residual polarization value Pr (50) becomes 50%, and also in this case, a piezoelectric body or the like is obtained having a strong spontaneous polarization.

Next, a reason why the poling treatment is performed at a temperature not lower than 100° C. (preferably not lower than 150° C. and more preferably not lower than 250° C.) will be explained in the following.

This is because, when the poling treatment electric field is applied while a piezoelectric body or the like of the substrate to be poled is heated to a temperature not lower than 100° C., the orientation of the crystal (polarization axis) can be changed and the characteristic of the piezoelectric body or the like can be improved by an amount of a vector component in a direction of the electric field applied in the changed orientation of the crystal (polarization axis).

For example, when a substrate including a ferroelectric body is used as the substrate to be poled 2, by the poling treatment as described above, it is possible to provide the ferroelectric body with the piezoelectric activity and to manufacture a piezoelectric body.

According to the present embodiment, by forming plasma at a position facing the substrate to be poled 2, it is possible to apply the poling treatment to the substrate to be poled 2. That is, it becomes possible to perform the poling treatment simply by a dry method.

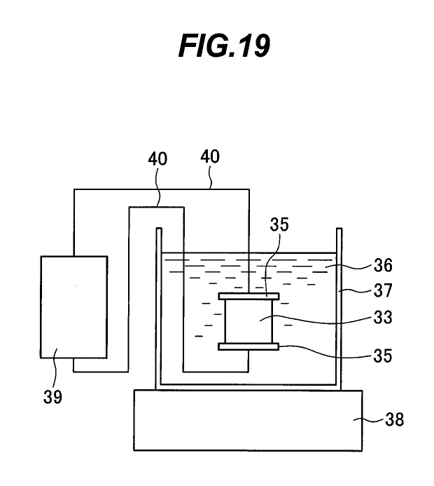

Further, the conventional poling device shown in FIG. 19 is a device applying the poling treatment to a bulk material and it is difficult to apply the poling treatment to a substrate including a thin film such as a ferroelectric film. On the other hand, in the plasma poling device according to the present embodiment, it is easy to apply the poling treatment to a substrate including a thin film such as a ferroelectric film.

Further, in the plasma poling device according to the present embodiment, it is possible to apply the poling treatment to a ferroelectric film formed on a wafer without dividing the wafer into chips in the poling treatment.

Further, while the voltage required for the power source is different depending on the thickness of the substrate to be poled, the plasma poling device according to the present embodiment can perform the poling treatment using a lower power source voltage than the conventional poling device, and therefore does not need a larger power source equipment than the conventional poling device.

Further, the plasma poling device according to the present embodiment performs the poling treatment using plasma, and therefore it is possible to reduce a poling treatment time and improve the productivity of a piezoelectric body, compared with the conventional poling device.

Further, the plasma poling device according to the present embodiment does not use oil as the conventional poling device, and does not evaporate the oil and deteriorate the work environment of a worker.

Note that, while in the present embodiment, plasma is formed at a position facing the substrate to be poled and the plasma poling treatment is performed at a temperature higher than the Curie temperature by 50° C., or a temperature not lower than 100° C. (preferably not lower than 150° C. and more preferably not lower than 250° C.), the poling treatment may be performed without using plasma at a temperature higher than the Curie temperature by 50° C. or a temperature not lower than 100° C. (preferably not lower than 150° C. and more preferably not lower than 250° C.), and, in this case, it is possible to improve the characteristics of a piezoelectric body or the like which has been poled. Here, as the poling treatment without using plasma, the poling treatment shown in FIG. 19 can be employed, for example.

### Second Embodiment

A manufacturing method of a piezoelectric body according to one aspect of the present invention will be explained. This manufacturing method of a piezoelectric body uses the plasma poling device shown in FIG. 1.

First, a substrate is prepared. In detail, a substrate like a silicon wafer, for example, is prepared, and, by means of polishing the rear surface of this substrate, the thickness of the silicon wafer is made smaller than that of the SEMI standard or the thickness of the substrate is made not larger than 500 μm (preferably not larger than 400 μm, more preferably not larger than 300 μm, and furthermore preferably not larger than 250 μm), and then an electrode film is formed on this substrate.

Note that, while, in the present embodiment, the electrode film is formed on the silicon wafer having a thickness smaller than that of the SEMI standard or on the substrate having a thickness not larger than 500 μm, another film or the like except the electrode film may be formed on the substrate.

Next, a piezoelectric material film is formed on the electrode film of the substrate. Here, a material which is applicable to the substrate to be poled 2 and explained in the first embodiment, or the like, can be used as the piezoelectric material film.

Next, the poling treatment is applied to the piezoelectric material film on the substrate by the same method as that in the first embodiment using the plasma poling device shown in FIG. 1. Thereby, it is possible to provide the piezoelectric material film with the piezoelectric activity and to form a piezoelectric body on the substrate.

In the present embodiment, a reason why the thickness of the silicon wafer is made smaller than that of the SEMI standard or the thickness of the substrate is made not larger than 500 μm is that the poling is unable to be performed sufficiently when the substrate thickness is large.

Details will be explained in the following by the use of FIG. 4. FIG. 4 is a schematic diagram showing a unimorph vibrator.

The piezoelectric body of the present embodiment corresponds to PZT shown in FIG. 4, and the substrate of the present embodiment corresponds to the vibration plate. A displacement volume V of the piezoelectric body (PZT) is expressed by following formula (1) and a generated pressure P of the piezoelectric body is expressed by following formula (2).

V=Vₕd₃₁(W³L/t²)×f(w,t,s) (1)

P=Vₕ(d₃₁t/sW²)g(w,t,s) (2)

Vₕ: Drive voltage of PZT

s: Elastic modulus of PZT

d₃₁: Piezoelectric constant

W: Width

t: Vibration plate thickness

L: Vibration plate length

Since the displacement volume V of the piezoelectric body is inversely proportional to a square of the vibration plate (Si substrate) thickness t as shown in above formula (1), the piezoelectric body is unable to move when the substrate thickness is large. Even when an electric field is applied to the piezoelectric material film in the poling treatment, if the piezoelectric material film is unable to move, it is difficult to pole the piezoelectric material film and it is not possible to provide the piezoelectric material film with the piezoelectric activity.

Accordingly, when the rear surface of the substrate is polished and the thickness of the substrate is made smaller to a thickness not larger than 500 μm (preferably not larger than 400 μm, more preferably not larger than 300 μm, and further more preferably not larger than 250 μm), the piezoelectric material film moves easily and it becomes possible to provide the piezoelectric material film with the piezoelectric activity.

Note that, while the plasma poling treatment is used in the present embodiment, the present embodiment may be carried out without using plasma. Also in this case, it is possible to improve the characteristic of the piezoelectric body or the like which has been poled. Here, as the poling treatment without using plasma, the poling treatment shown FIG. 19 can be employed, for example.

### Third Embodiment

A manufacturing method of a piezoelectric body according to one aspect of the present embodiment will be explained. This manufacturing method of a piezoelectric body uses the plasma poling device shown in FIG. 1.

While the substrate thickness is made smaller to facilitate the poling in the second embodiment, in the present embodiment, the temperature of the piezoelectric material film is made not lower than the Curie temperature (preferably temperature higher than the Curie temperature by 50° C.), not lower than a temperature at which the residual polarization value of the hysteresis curve becomes 0%, or not lower than 100° C. (preferably not lower than 150° C. and more preferably not lower than 250° C.) to facilitate the poling.

Details will be explained in the following.

First, a substrate is prepared. In detail, a substrate like a silicon wafer, for example, is prepared and an electrode film is formed on this substrate. Here, the thickness of the substrate may be not smaller than 500 μm, or may be a thickness of the SEMI standard. Further, while the present embodiment uses the substrate on which the electrode film is formed, a substrate on which another film or the like except the electrode film is formed, may be used.

Next, a piezoelectric material film is formed on the electrode film of the substrate. Here, as the piezoelectric material film, a material which is applicable to the substrate to be poled 2 and explained in the first embodiment, or the like, can be used.

Next, the poling treatment is performed by means of applying an electric field to the piezoelectric material film on the substrate, using the plasma poling device shown in FIG. 1. In detail, the piezoelectric material film is heated to a first temperature not lower than the Curie temperature (preferably not lower than a temperature higher than the Curie temperature by 50° C.) or not lower than 100° C. (preferably not lower than 150° C. and more preferably not lower than 250° C.), and the poling treatment is applied to the piezoelectric material film in this state. In the present embodiment, the first temperature is set to 500° C. After the poling treatment has been performed at the first temperature, the temperature is decreased from the first temperature to a second temperature while the poling treatment is applied to the piezoelectric material film. The second temperature is a temperature not lower than 50° C. and also lower than the first temperature, a temperature not lower than a temperature at which the residual polarization value becomes 50% of a residual polarization value at the room temperature in the hysteresis curve of the piezoelectric material film, or a temperature not lower than 100° C. and also lower than the first temperature. In the present embodiment, the second temperature is set to 250° C. Subsequently, the temperature of the piezoelectric material film is decreased from the second temperature to the room temperature. Here, except for the poling treatment temperature, the same method as that in the first embodiment is used.

According to the present embodiment, since the poling treatment is applied to the piezoelectric material film at the first temperature, it is possible to provide the piezoelectric material film with a sufficient piezoelectric activity without reducing the substrate thickness.

Further, in the present embodiment, the poling treatment is continued while the temperature of the piezoelectric material film is decreased from the first temperature to the second temperature (temperature not lower than 50° C. and also lower than the first temperature, or the like), and thereby it is possible to provide the piezoelectric material film with a sufficient piezoelectric activity without reducing the substrate thickness.

Note that, in the present embodiment, while the temperature of the piezoelectric material film is decreased to the second temperature while the poling treatment is continued to be applied to the piezoelectric material film, the poling treatment may be terminated after the poling treatment has been performed at the first temperature, or the poling treatment may be performed while the temperature of the piezoelectric material film is increased from the second temperature to the first temperature.

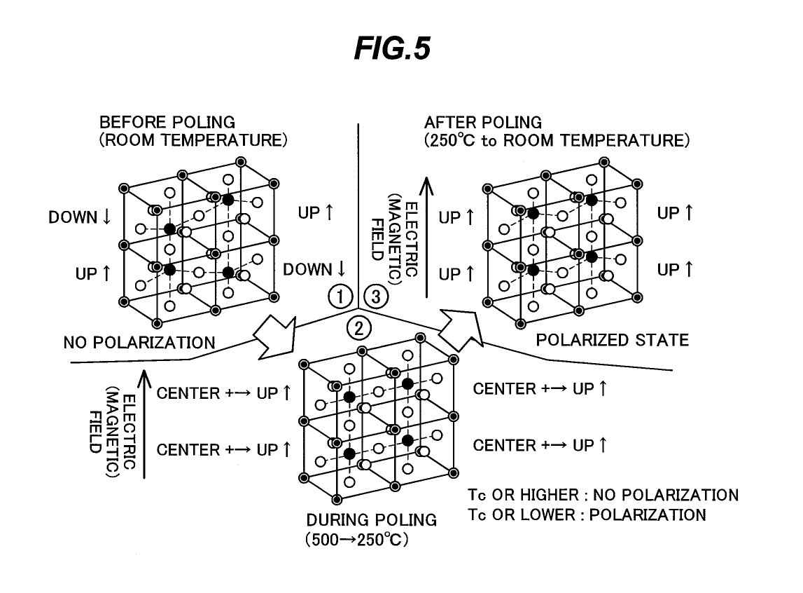

FIG. 5 is a diagram for explaining a reason why the poling treatment is performed easily even for a large substrate thickness when the poling treatment is applied to the piezoelectric material film at the temperature of the present embodiment.

The piezoelectric body has a smaller hysteresis as the temperature is increased, and the piezoelectricity becomes smaller as the hysteresis is smaller. The smaller piezoelectricity means that, even in the state that the substrate thickness is so large that the piezoelectric material film on a substrate does not move easily, the poling is performed only by a small movement of the piezoelectric material film and thereby the poling is easily performed. Note that the hysteresis disappears when the temperature of the piezoelectric body becomes the Curie temperature Tc.

That is, as shown in FIG. 5, the piezoelectric material film before the poling treatment has a state without polarization at the room temperature. Next, the poling treatment is performed by means of applying an electric field in the state that the piezoelectric material film is heated to 500° C., and, after that, the temperature of the piezoelectric material film is decreased to 250° C. while the poling treatment is continued. Here, the piezoelectric material film has a state without polarization at a temperature not lower than the Curie temperature Tc and has a state having polarization at a temperature lower than the Curie temperature Tc. Next, the poling treatment is terminated and the temperature of the piezoelectric material film is decreased to the room temperature. The piezoelectric material film has a polarized state also at the room temperature.

Note that, while the plasma poling treatment is used in the present embodiment, the present embodiment may be carried out without using plasma. Also in this case, it is possible to improve the characteristics of the piezoelectric body or the like which has been poled. Here, as the poling treatment without using plasma, the poling treatment shown in FIG. 19 can be employed, for example.

### Fourth Embodiment

### Plasma Poling Device

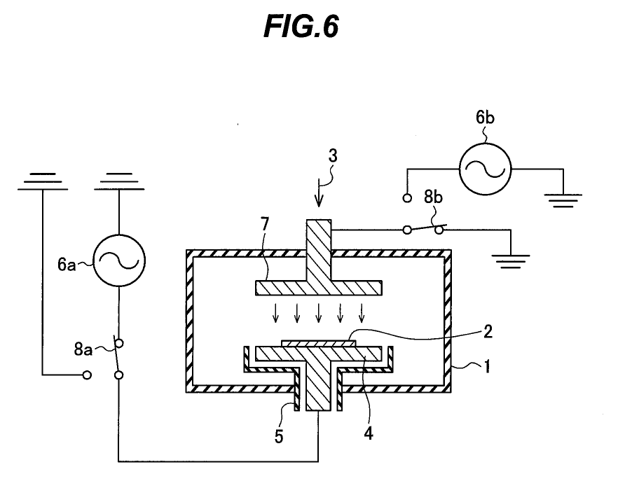

FIG. 6 is a cross-sectional view showing a plasma poling device according to one aspect of the present invention, and the same sign is provided for the same part as that in FIG. 1 and only a different point will be explained.

A holding electrode 4 is electrically connected to a high frequency power source 6a or the ground potential via a switch 8a, and a high frequency power or the ground potential is applied to the holding electrode 4 by the switch 8a. Further, a gas shower electrode 7 is electrically connected to a high frequency power source 6b or the ground potential via a switch 8b, and a high frequency power or the ground potential is applied to the gas shower electrode 7 by the switch 8b. Note that, while the high frequency power sources 6a and 6b are used in the present embodiment, other power sources, for example, DC power sources or microwave power sources may be used.

Further, the plasma poling device includes the switches 8a and 8b, the high frequency power sources 6a and 6b, a plasma forming gas supply mechanism 3, and a control unit controlling an exhaustion pump and the like (not shown in the drawing), and this control unit is configured to control the plasma poling device so as to perform the poling treatment as will be described in the following.

<Poling Treatment Method>

Next, a method of applying the poling treatment to the substrate to be poled using the above plasma poling device will be explained.

[1] Substrate to be Poled

First, a substrate to be poled 2 is prepared. As the substrate to be poled 2, the same material as that in the first embodiment can be used.

[2] Poling Treatment

Next, as in the first embodiment, the substrate to be poled 2 is held on the holding electrode 4 in a poling chamber 1.

(1) Case of performing the poling treatment by connecting the high frequency power sources 6a and 6b and the ground potential to the holding electrode 4 and the gas shower electrode 7 in a first connection state

The first connection state is a state in which the high frequency power source 6a is connected to the holding electrode 4 by the switch 8a and the ground potential is connected to the gas shower electrode 7 by the switch 8b. A specific method of applying the poling treatment to the substrate to be poled 2 in this state is the same as that in the first embodiment and explanation will be omitted.

(2) Case of performing the poling treatment by connecting the high frequency power sources 6a and 6b and the ground potential to the holding electrode 4 and the gas shower electrode 7 in a second connection state

The second connection state is a state in which the ground potential is connected to the holding electrode 4 by the switch 8a and the high frequency power source 6b is connected to the gas shower electrode 7 by the switch 8b. A specific method of applying the poling treatment to the substrate to be poled 2 in this state is as follows.

The inside of the poling chamber 1 is exhausted into vacuum by the exhaustion pump. Subsequently, a plasma forming gas such as Ar in a shower state is introduced into the poling chamber 1 from supply ports of the gas shower electrode 7 and supplied onto the surface of the substrate to be poled 2. This supplied plasma forming gas travels between the holding electrode 4 and an earth shield 5 and is exhausted to the outside of the poling chamber 1 by the exhaustion pump. Then, the inside of the poling chamber 1 is set to a plasma forming gas atmosphere by controlling the pressure and plasma forming gas flow rate into predetermined values by means of the balance between a plasma forming gas supply amount and the exhaustion. Further, a high frequency (RF) power of 380 kHz and 13.56 MHz, for example, is applied to the gas shower electrode 7 from the high frequency power source 6b to generate plasma and thus the poling treatment is applied to the substrate to be poled 2. Preferably, this poling treatment is performed in the following conditions: the pressure is 0.01 Pa to the air pressure; the power source is a DC power source, a high-frequency power source, or a microwave power source; the treatment temperature is not lower than the Curie temperature of the substrate to be poled 2 (preferably not lower than a temperature higher than the Curie temperature by 50° C.), not lower than a temperature at which the residual polarization value in the hysteresis curve of the substrate to be poled 2 becomes 0%, or not lower than 100° C. (preferably not lower than 150° C. and more preferably not lower than 250° C.); and the DC voltage component in the plasma formation is ±50 V to ±2 kV. Subsequently, after the poling treatment has been performed for a predetermined time, the supply of the plasma forming gas from the supply ports of the gas shower electrode 7 is terminated and the poling treatment is finished.

For example, when a substrate including a ferroelectric body is used as the substrate to be poled 2, by the poling treatment as described above, it is possible to provide the ferroelectric body with the piezoelectric activity and to manufacture a piezoelectric body.

Also in the present embodiment, it is possible to obtain the same effect as that of the first embodiment.

Note that the first embodiment to the fourth embodiment may be carried out in combination with each other, and, for example, the second embodiment may be combined with the third embodiment, the second embodiment may be combined with the fourth embodiment, and the third embodiment may be combined with the fourth embodiment.

### Fifth Embodiment

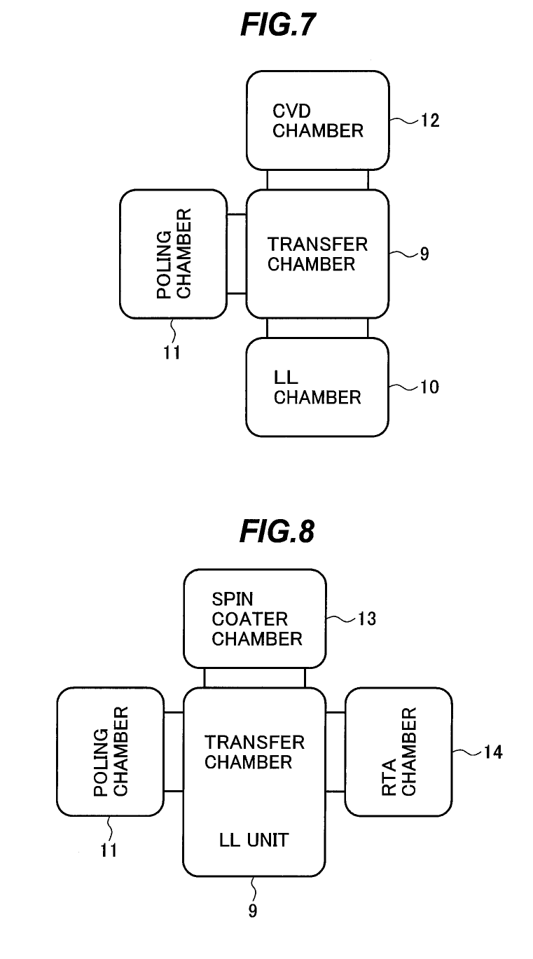

FIG. 7 is a plan view schematically showing a film forming device according to one aspect of the present invention. This film forming device includes a transfer chamber 9 having a transfer mechanism, an LL chamber 10, a poling chamber 11 having a plasma poling device, and a CVD chamber 12 having a CVD device. Each of the transfer chamber 9, the LL chamber 10, the poling chamber 11, and the CVD chamber 12 has an exhaustion mechanism for vacuum exhaustion. An MOCVD device or a plasma CVD device may be used as the CVD device, for example.

A substrate (not shown in the drawing) is introduced into the LL chamber 10, and the substrate is transferred to the CVD chamber 12 via the transfer chamber 9 by the transfer mechanism. Subsequently, a CVD film is formed on the substrate in the CVD chamber 12. Next, the substrate is transferred from the CVD chamber 12 to the poling chamber 11 by the transfer mechanism, and the poling treatment is applied to the substrate in the poling chamber 11. Any of the methods in the first to fourth embodiments is used as a method for the poling treatment. Subsequently, the substrate is transferred from the poling chamber 11 to the LL chamber 10 by the transfer mechanism, and the substrate is taken out from the LL chamber 10.

Note that, while the CVD chamber 12 having the CVD device is used in the present embodiment, the present embodiment may be carried out by means of changing the CVD chamber 12 into a sputtering chamber having a sputtering device or an evaporation chamber having an evaporation device.

### Sixth Embodiment

FIG. 8 is a plan view schematically showing a film forming device according to one aspect of the present invention. This film forming device includes a transfer chamber 9 having an LL unit and a transfer mechanism, a poling chamber 11 having a plasma poling device, a spin coater chamber 13 having a spin coating device, and an RTA chamber 14 having a lamp annealing (RTA: Rapid Thermal Anneal) device. Each of the transfer chamber 9, the poling chamber 11, the spin coater chamber 13, and the RTA chamber 14 includes an exhaustion mechanism for vacuum exhaustion.

A substrate (not shown in the drawing) is introduced into the LL unit of the transfer chamber 9, and the substrate is transferred to the spin coater chamber 13 by the transfer mechanism. Next, a film to be poled such as a piezoelectric material film is formed on the substrate by the spin coating device in this spin coater chamber 13. Subsequently, the substrate is transferred from the spin coater chamber 13 to the RTA chamber 14 by the transfer mechanism, and the piezoelectric material film on the substrate is subjected to a thermal treatment and crystallized by the lamp annealing device in the RTA chamber 14. Next, the substrate is transferred from the RTA chamber 14 to the poling chamber 11 by the transfer mechanism, and the poling treatment is applied to the piezoelectric material film on the substrate in the poling chamber 11. Any of the methods in the first to fourth embodiments is used as a method for the poling treatment. Next, the substrate is transferred from the poling chamber 11 to the LL unit and the substrate is taken out from the LL unit.

According to the present embodiment, the spin coating, the lamp annealing and the poling treatment can be performed continuously without exposure to the air, and it is possible to improve film quality.

Note that, while the lamp annealing device is used in the present embodiment, a pressure-type lamp annealing device may be used.

### Seventh Embodiment

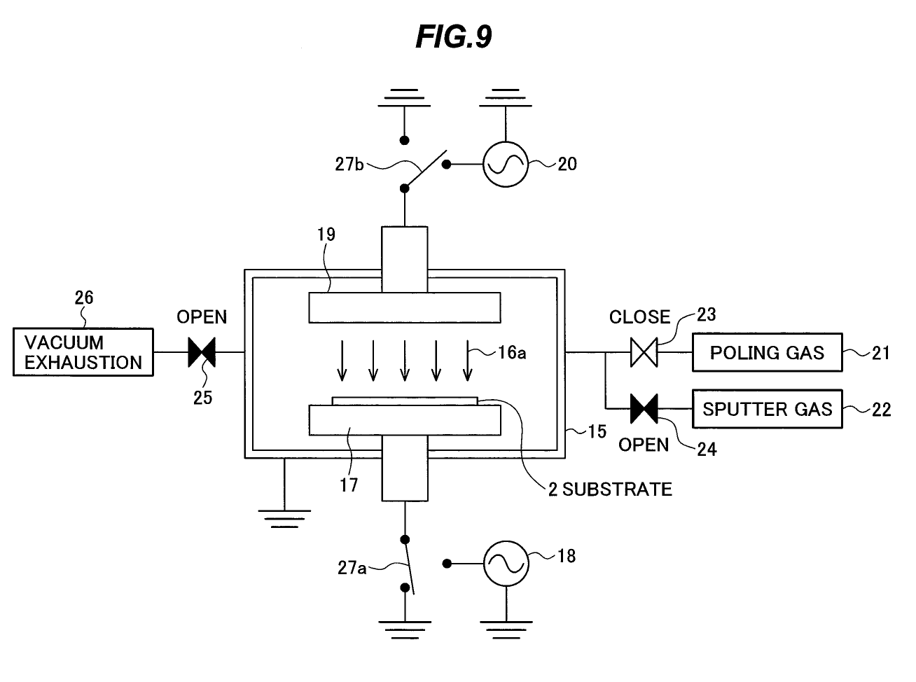

FIG. 9 is a cross-sectional view showing a state in which sputter film formation is performed by a sputtering device according to one aspect of the present invention. This sputtering device includes a plasma poling device.

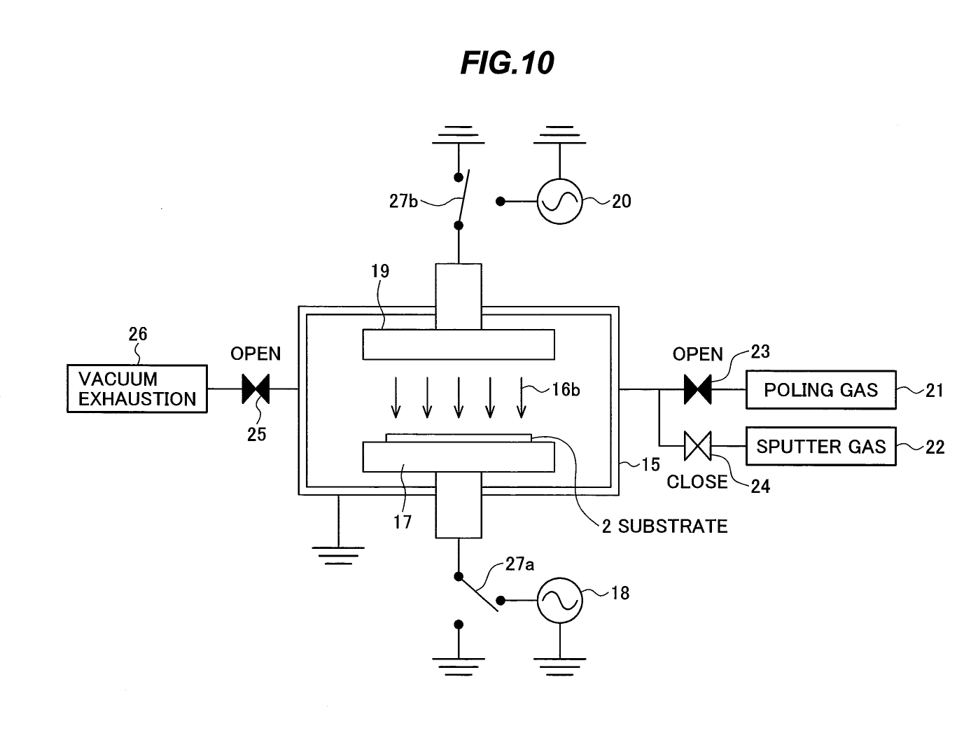

FIG. 10 is a cross-sectional view showing a state in which the poling treatment is performed by the sputtering device shown in FIG. 9.

First, a substrate 2 is held on a holding electrode 17 as shown in FIG. 9. Subsequently, a valve 23 is closed, valves 24 and 25 are opened, the inside of a chamber 15 is exhausted into vacuum by a vacuum exhaustion mechanism 26, and sputter gas is supplied into the chamber 15 by a sputter gas supply source 22 and controlled so as to have a desired pressure.

Next, the holding electrode 17 is connected to the ground potential by a switch 27a, and an opposite electrode 19 which has a sputtering target (not shown in the drawing) disposed facing the substrate 2 is connected to a high frequency power source 20 by a switch 27b. Thereby, the ground potential is applied to the substrate 2 and a high frequency power is applied to the sputtering target, and a film to be poled such as a piezoelectric material film is formed on the substrate 2 by sputtered particles 16a.

Next, as shown in FIG. 10, the valve 24 is closed, the valves 23 and 25 are opened, the inside of the chamber 15 is exhausted into vacuum by the vacuum exhaustion mechanism 26, and poling gas is supplied into the chamber 15 by a poling gas supply source 21 and controlled so as to have a desired pressure.

Next, the holding electrode 17 is connected to the high frequency power source 18 by the switch 27a and the opposite electrode 19 is connected to the ground potential by the switch 27b. Thereby, a high frequency power is applied to the substrate 2, the ground potential is applied to the opposite electrode 19, and the poling treatment is applied to the film to be poled on the substrate 2. Any of the methods in the first to fourth embodiments is used as a method for the poling treatment.

According to the present embodiment, the sputter film formation and the poling treatment can be performed continuously without exposure to the air, and it is possible to improve the film quality.

### Eighth Embodiment

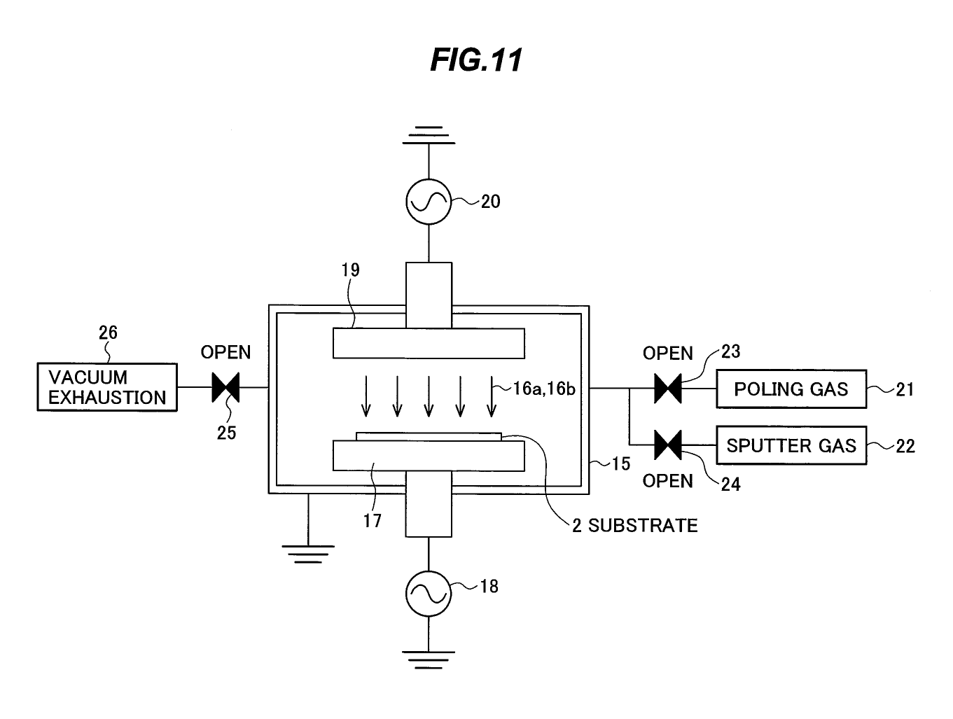

FIG. 11 is a cross-sectional view showing a state in which the sputter film formation and the poling treatment are performed at the same time by a sputtering device according to one aspect of the present invention. This sputtering device includes a plasma poling device.

As shown in FIG. 11, a substrate 2 is held on a holding electrode 17. Subsequently, valves 23 to 25 are opened, the inside of a chamber 15 is exhausted into vacuum by a vacuum exhaustion mechanism 26, and poling gas and sputter gas are supplied into the chamber 15 by a poling gas supply source 21 and a sputter gas supply source 22 and controlled so as to have desired pressures.

Next, the holding electrode 17 is connected to a high frequency power source 18 and an opposite electrode 19 which has a sputtering target (not shown in the drawing) disposed facing the substrate 2 is connected to a high frequency power source 20. Thereby, a high frequency power is applied to the substrate 2 and a high frequency power is applied to the sputtering target, and the poling treatment is applied to a sputtered film while the sputtered film is formed on the substrate 2, by sputtered particles 16a and poling gas 16b.

### Ninth Embodiment

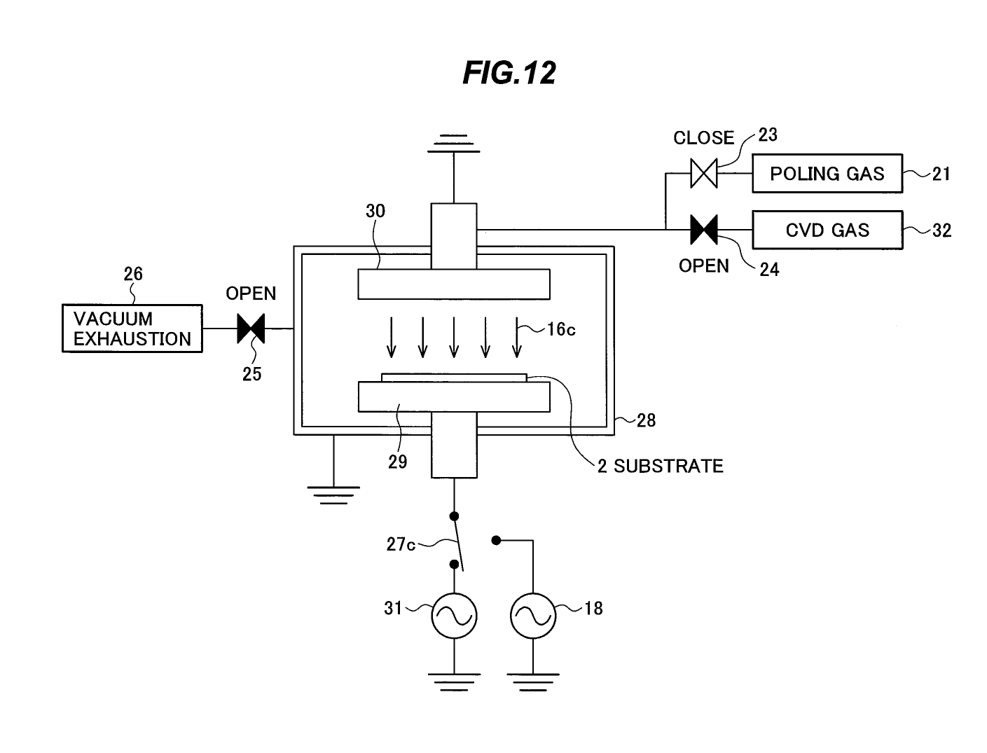

FIG. 12 is a cross-sectional view showing a state in which CVD film formation is performed by a plasma CVD device according one aspect of the present invention. This plasma CVD device includes a plasma poling device.

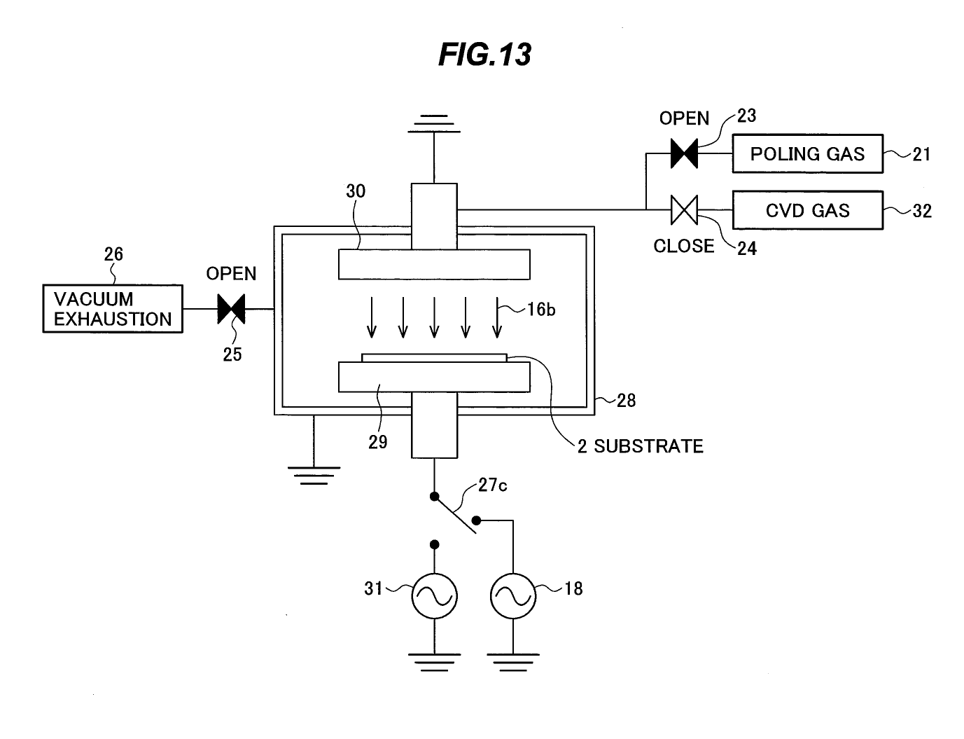

FIG. 13 is a cross-sectional view showing a state in which the poling treatment is performed by the plasma CVD device shown in FIG. 12.

First, as shown in FIG. 12, a substrate 2 is held on a holding electrode 29. Subsequently, a valve 23 is closed, valves 24 and 25 are opened, the inside of a chamber 28 is exhausted into vacuum by a vacuum exhaustion mechanism 26, and CVD gas is supplied into the chamber 28 by a CVD gas supply source 32 and controlled so as to have a desired pressure.

Next, the holding electrode 29 is connected to a high frequency power source for CVD 31 by a switch 27c. An opposite electrode 30 which is disposed facing the substrate 2 is connected to the ground potential. Thereby, a high frequency power for CVD is applied to the substrate 2, the ground potential is applied to the opposite electrode 30, and a film to be poled like a piezoelectric material film is formed on the substrate 2 by CVD gas 16c.

Next, as shown in FIG. 13, the valve 24 is closed, the valves 23 and 25 are opened, the inside of the chamber is exhausted into vacuum by the vacuum exhaustion mechanism 26, and poling gas is supplied into the chamber 28 by a poling gas supply source 21 and controlled so as to have a desired pressure.

Next, the holding electrode 29 is connected to a high frequency power source for poling 18 by the switch 27c. The opposite electrode 30 is connected to the ground potential. Thereby, a high frequency power is applied to the substrate 2, the ground potential is applied to the opposite electrode 30, and the poling treatment is applied to the film to be poled on the substrate 2. Any of the methods in the first to fourth embodiments is used as a method for the poling treatment.

According to the present embodiment, the CVD film formation, and the poling treatment can be performed continuously without exposure to the air, and it is possible to improve the film quality.

### Tenth Embodiment

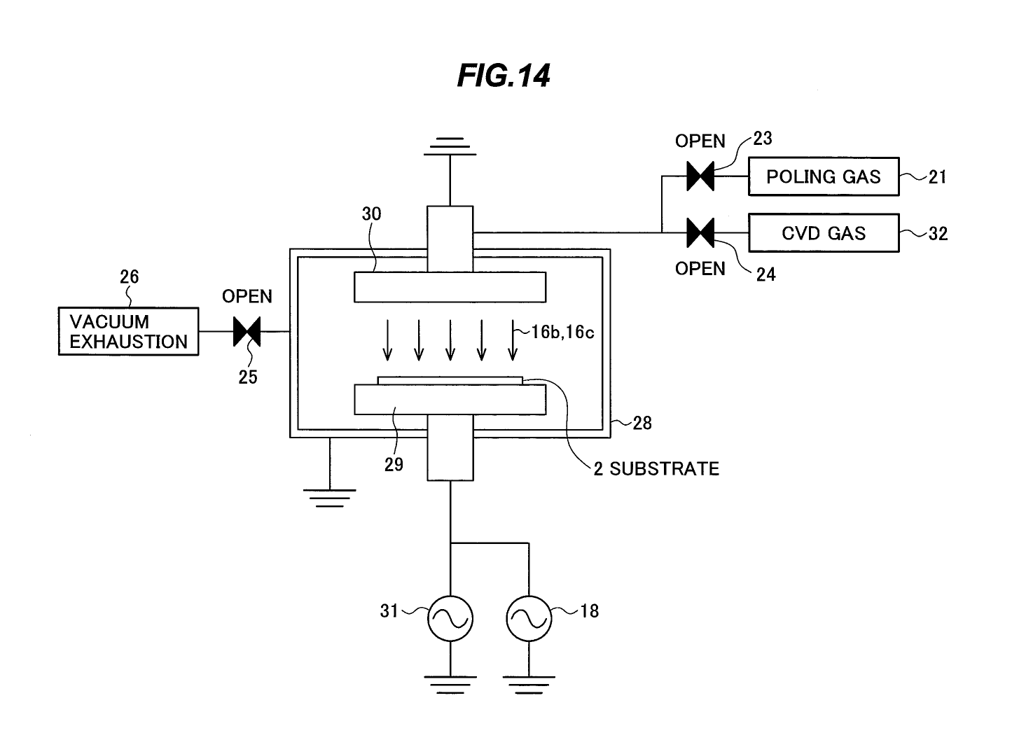

FIG. 14 is a cross-sectional view showing a state in which the CVD film formation and the poling treatment are performed at the same time by a plasma CVD device according to one aspect of the present invention. This plasma CVD device includes a plasma poling device.

As shown in FIG. 14, a substrate 2 is held on a holding electrode 29. Subsequently, valves 23 to 25 are opened, the inside of a chamber 28 is exhausted into vacuum by a vacuum exhaustion mechanism 26, and poling gas 16b and CVD gas 16c are supplied into the chamber 28 by a poling gas supply source 21 and a CVD gas supply source 32 and controlled so as to have desired pressures.

Next, a high frequency power for CVD and a high frequency power for poling are applied to the holding electrode 29 by a high frequency power source for CVD 31 and a high frequency power source for poling 18. Thereby, the poling treatment is applied to a CVD film while the CVD film is formed on the substrate 2, by the CVD gas 16c and the poling gas 16b.

### Eleventh Embodiment

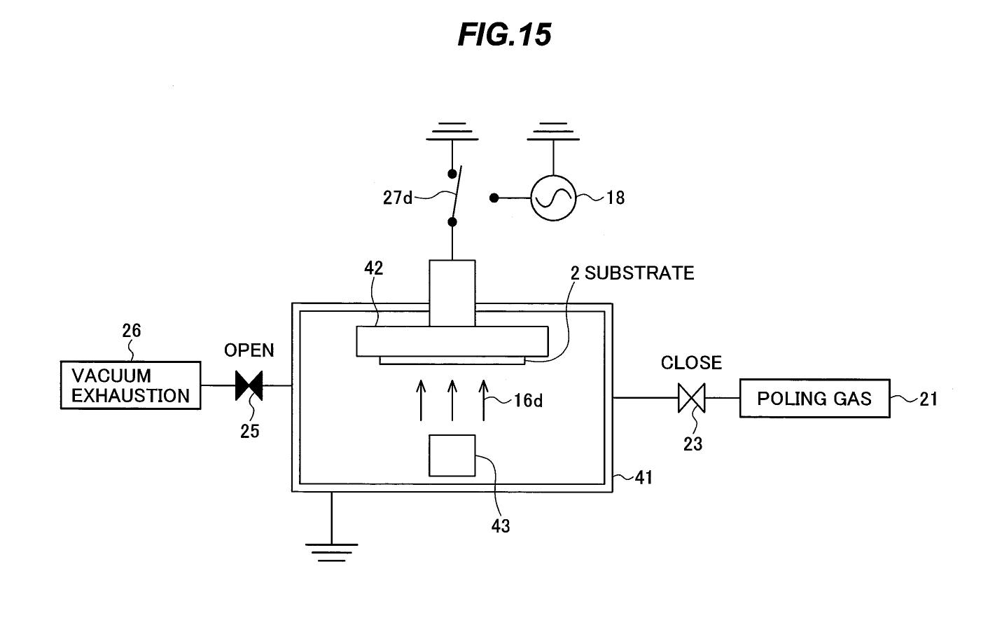

FIG. 15 is a cross-sectional view showing a state in which evaporation film formation is performed by an evaporation device according to one aspect of the present invention. This evaporation device includes a plasma poling device.

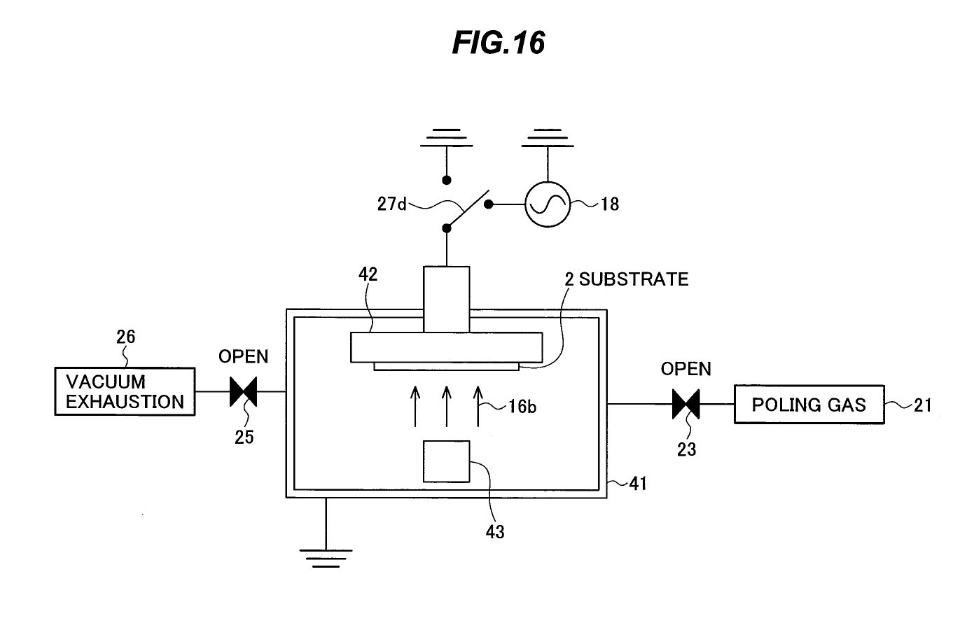

FIG. 16 is a cross-sectional view showing a state in which the poling treatment is performed by the evaporation device shown in FIG. 15.

First, as shown in FIG. 15, a substrate 2 is held on a holding electrode 42. Subsequently, a valve 23 is closed, a valve 25 is opened, and the inside of a chamber 41 is exhausted into vacuum by a vacuum exhaustion mechanism 26 and controlled so as to have a desired pressure.

Next, an evaporation material 16d is supplied onto the surface of the substrate 2 by an evaporation source 43. Thereby, a film to be poled such as a piezoelectric material film is formed on the substrate 2.

Next, as shown in FIG. 16, the valves 23 and 25 are opened, the inside of the chamber 41 is exhausted into vacuum by the vacuum exhaustion mechanism 26, and poling gas 16b is supplied into the chamber 41 by a poling gas supply source 21 and controlled so as to have a desired pressure.

Next, the holding electrode 42 is connected to a high frequency power source 18 by a switch 27d. Thereby, a high frequency power is applied to the substrate 2 and the poling treatment is applied to the film to be poled on the substrate 2. Any of the methods in the first to fourth embodiments is employed as a method for the poling treatment.

According to the present embodiment, the evaporation film formation and the poling treatment are performed continuously without exposure to the air and it is possible to improve the film quality.

### Twelfth Embodiment

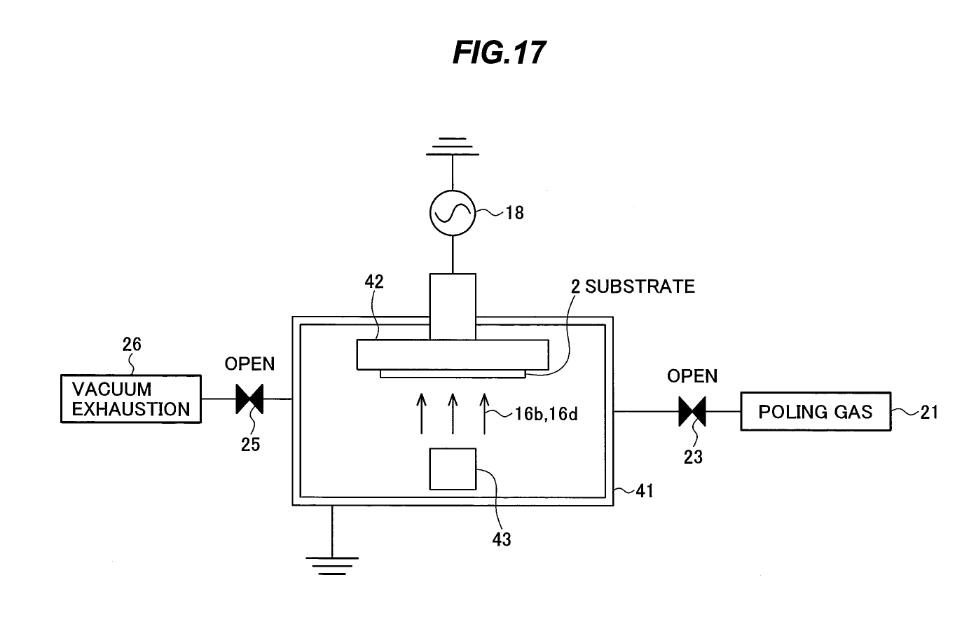

FIG. 17 is a cross-sectional view showing a state in which the evaporation film formation and the poling treatment are performed at the same time by an evaporation device according to one aspect of the present invention. This evaporation device includes a plasma poling device.

As shown in FIG. 17, a substrate 2 is held on a holding electrode 42. Subsequently, valves 23 and 25 are opened, the inside of a chamber 41 is exhausted into vacuum by a vacuum exhaustion mechanism 26, and poling gas 16b is supplied into the chamber 41 by a poling gas supply source 21 and controlled so as to have a desired pressure.

Next, a high frequency power is applied to the holding electrode 42 by a high frequency power source 18 and also an evaporation material 16d is supplied onto the surface of the substrate 2 by an evaporation source 43. Thereby, while a piezoelectric material film is formed on the substrate 2 by evaporation, the poling treatment is applied to the piezoelectric material film.

### Thirteenth Embodiment

An etching device according to one aspect of the present invention includes any of the plasma poling devices explained in the first to fourth embodiments. A plasma etching device can be used as the etching device, for example.

A film to be poled such as a piezoelectric material film is formed on a substrate by a film forming device, for example, and the film to be poled is processed by the etching device, and, after that, the poling treatment can be applied to the processed film to be poled by the plasma poling device. For example, a capacitor is formed by performing plasma etching on the film to be poled, and then, a step of applying the poling treatment to the capacitor may be carried out.

### Fourteenth Embodiment

### Plasma Poling Device

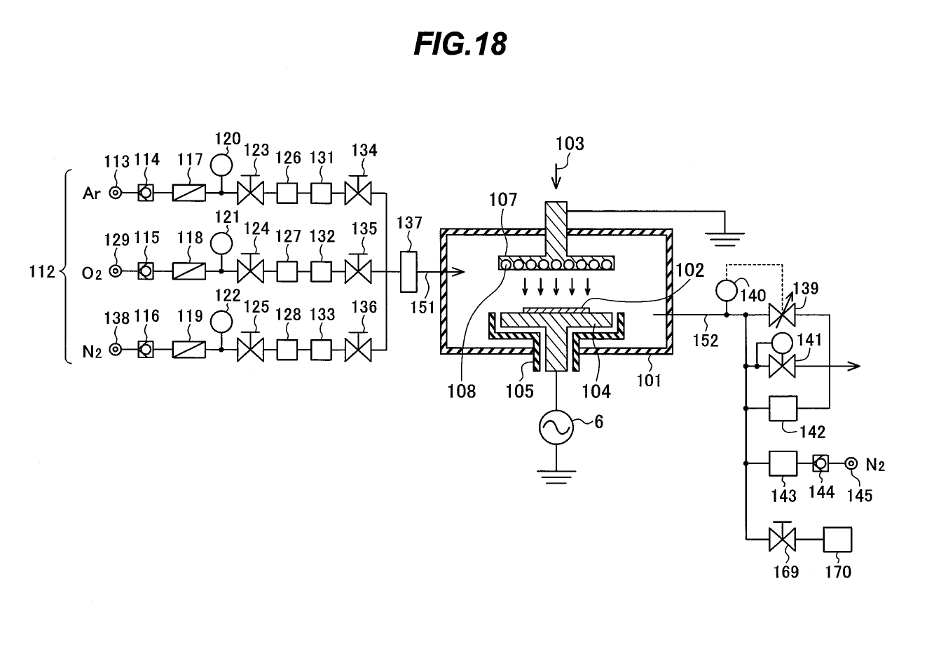

FIG. 18 is a cross-sectional view schematically showing a pressure-type lamp annealing device according to one aspect of the present invention. This pressure-type lamp annealing device includes a plasma poling device. The pressure-type lamp annealing device is a device for performing lamp anneal treatment (RTA: Rapid Thermal Anneal) in a pressurized state to perform the poling treatment.

The RTA device includes a chamber 101 for pressure, and the chamber 101 is configured to be water-cooled by a cooling mechanism which is not shown in the drawing. A holding electrode 104 holding a substrate to be poled 102 is disposed in the lower part in the chamber 101. Details of the substrate to be poled 102 are the same as those in the first embodiment and explanation will be omitted.

The holding electrode 104 is electrically connected to a high frequency power source 6, and the holding electrode 104 functions also as an RF application electrode. The circumference and the lower part of the holding electrode 104 are shielded by an earth shield 105. Note that, while the high frequency power source 6 is used in the present embodiment, another power source, for example, a DC power source or a microwave power source may be used.

In the upper part in the chamber 101, a gas shower electrode (opposite electrode) 107 is disposed at a position facing the holding electrode 104 in parallel. These are a pair of parallel flat plate type electrodes. The gas shower electrode is connected to the ground potential. Note that, while the power source is connected to the holding electrode 104 and the ground potential is connected to the gas shower electrode in the present embodiment, the ground potential may be connected to the holding electrode 104 and the power source may be connected to the gas shower electrode.

On the lower surface of the gas shower electrode 107, there are formed plural supply ports (not shown in the drawing) supplying a plasma forming gas in a shower state to the substrate to be poled 102 on the surface side (space between the gas shower electrode 107 and the holding electrode 104). As the plasma forming gas, Ar, He, N₂, O₂, F₂, CₓF_{y}, air or the like can be used, for example.

A gas introduction path (not shown in the drawing) is provided inside the gas shower electrode 107. One side of this gas introduction path is connected to the above supply ports, and the other side of the gas introduction path is connected to a plasma forming gas supply mechanism 103. Further, the chamber 101 is provided with an exhaustion port exhausting the inside of the chamber 101 into vacuum. This exhaustion port is connected to an exhaustion pump (not shown in the drawing).

In the upper part in the chamber 101, a lamp heater 108 is disposed facing the holding electrode 104. The present device includes an exhaustion duct (not shown in the drawing) exhausting the heat of the lamp heater 108.

The chamber 101 is connected to a pressure line (pressure mechanism) 112. The pressure line 112 includes a pressure line of argon gas, a pressure line of oxygen gas and a pressure line of nitrogen gas.

The pressure line of argon gas is provided with an argon gas supply source 113. This argon gas supply source 113 is connected to a check valve 114 via a first pipe, and this check valve 114 is connected to a filter 117 for removing impurities, via a second pipe. This filter 117 is connected to a valve 123 via a third pipe, and the third pipe is connected to a pressure gauge 120. The valve 123 is connected to a regulator 126 via a fourth pipe, and this regulator 126 is connected to a mass flow controller 131 via a fifth pipe. The regulator 126 increases gas pressure gradually and sets a pressure difference between the up-stream side and the down-stream side of the mass flow controller 131 to a predetermined pressure. The mass flow controller 131 is connected to a valve 134 via a sixth pipe, and this valve 134 is connected to a heating unit 137 via a seventh pipe. The heating unit 137 makes gas temperature constant (e.g., temperature of approximately 40 to 50° C.) for stabilizing the process. The heating unit 137 is connected to the chamber 101 via a eighth pipe 151.

The pressure line of oxygen gas has the same configuration as the pressure line of argon gas. In detail, the pressure line of oxygen gas is provided with an oxygen gas supply source 129. This oxygen gas supply source 129 is connected to a check valve 115 via a first pipe, and this check valve 115 is connected to a filter 118 for removing impurities, via a second pipe. This filter 118 is connected to a valve 124 via a third pipe, and the third pipe is connected to a pressure gauge 121. The valve 124 is connected to a regulator 127 via a fourth pipe, and this regulator 127 is connected to a mass flow controller 132 via a fifth pipe. The mass flow controller 132 is connected to a valve 135 via a sixth pipe, and this valve 135 is connected to a heating unit 137 via a seventh pipe. The heating unit 137 is connected to the chamber 101 via an eighth pipe 151.

The pressure line of nitrogen gas has the same configuration as the pressure line of argon gas. In detail, the pressure line of nitrogen gas is provided with a nitrogen gas supply source 138. This nitrogen gas supply source 138 is connected to a check valve 116 via a first pipe, and this check valve 116 is connected to a filter 119 for removing impurities, via a second pipe. This filter 119 is connected to a valve 125 via a third pipe, and the third pipe is connected to a pressure gauge 122. The valve 125 is connected to a regulator 128 via a fourth pipe, and this regulator 128 is connected to a mass flow controller 133 via a fifth pipe. The mass flow controller 133 is connected to a valve 136 via a sixth pipe, and this valve 136 is connected to a heating unit 137 via a seventh pipe. The heating unit 137 is connected to the chamber 101 via an eighth pipe 151.

Further, the chamber 101 is connected to a pressure adjusting line. The inside of the chamber 101 is configured to be pressurized to a predetermined pressure (e.g., pressure lower than 1 MPa) by this pressure adjusting line and the above pressure line 112. The pressure adjusting line is provided with a variable valve 139, and one side of this variable valve 139 is connected to the chamber via a ninth pipe 152. The ninth pipe 152 is connected to a pressure gauge 140, and the pressure inside the chamber 101 is configured to be measured by this pressure gauge 140. The other side of the variable valve 139 is connected to a tenth pipe.

Further, the chamber 101 is connected to a safety line. This safety line is a line for reducing the pressure inside the chamber 101 to the air pressure when the inside of the chamber is abnormally pressurized excessively to a pressure higher than a predetermined pressure. The safety line is provided with a release valve 141. One side of this release valve 141 is connected to the chamber 101 via the ninth pipe 152, and the other side of the release valve 141 is connected to the tenth pipe. The release valve 141 is configured to cause the gas to flow when a predetermined pressure is applied.

Further, the chamber 101 is connected to an air release line. This air release line is a line returning the pressure inside the chamber 101 which is pressurized normally, to the air pressure. The air release line is provided with a release valve 142. One side of this release valve 142 is connected to the chamber 101 via the ninth pipe 152, and the other side of the release valve 142 is connected to the tenth pipe. The release valve 142 is configured to cause the gas inside the chamber 101 to flow gradually for returning the pressure inside the chamber 101 to the air pressure.

Further, the chamber 101 is connected to a line returning a reduced pressure state to the air pressure. This line is a line returning a reduced pressure state to the air pressure when the chamber 101 has the reduced pressure state (vacuum state). The above line is provided with a leak valve 143. One side of this leak valve 143 is connected to the inside of the chamber 101 via the ninth pipe 152, and the other side of the leak valve 143 is connected to a check valve 144 via an eleventh pipe. This check valve 144 is connected to a nitrogen gas supply source 145 via a twelfth pipe. That is, the above line is configured to return the pressure inside the chamber 101 to the air pressure by introducing nitrogen gas gradually into the chamber 101 from the nitrogen gas supply source 145 via the check valve 144 and the leak valve 143.

Further, the chamber 101 is connected to a vacuum exhaustion line for causing the inside of the chamber to have a reduced pressure state. This vacuum exhaustion line includes a valve 169, and one end of this valve 169 is connected to the inside of the chamber 101 via a pipe. The other end of the valve 169 is connected to a vacuum pump 170 via a pipe. This vacuum exhaustion line is used when vacuum exhaustion is performed once before the pressure RTA is performed, for example.

Further, the pressure-type lamp annealing device includes a control unit (not shown in the drawing) controlling the high frequency power source 6, the plasma forming gas supply mechanism 103, the lamp heater 108, the pressure line 112, the exhaustion pump, and the like, and this control unit controls the pressure-type lamp annealing device so as to perform the poling treatment in the same manner as in RTA treatment to be described below and as in the first embodiment.

Further, the pressure-type lamp annealing device may include a temperature control mechanism controlling the temperature of the substrate to be poled 102 to various values in the poling treatment.

Next, the operation of the above pressure-type lamp annealing device will be explained. As an example of this operation, there will be explained a method of fabricating a ferroelectric capacitor of PZT (lead zirconate tianate) which is an example of an organic metal material, using the above pressure-type lamp annealing device.

First, a silicon oxide film (SiO₂ film) is formed on a 6-inch silicon wafer by a thermal oxidation method, and a lower electrode is formed on this silicon oxide film. Subsequently, a PZT film is coated on this lower electrode by a sol-gel method. A substrate to be poled 102 is prepared in this manner.

After that, the RTA treatment is performed in an oxygen atmosphere at 600° C. for 1 minute using the above pressure-type lamp annealing device. Details will be explained in the following.

The substrate to be poled 102 is introduced into the chamber 101, and this substrate to be poled 102 is held on the holding electrode 104. Subsequently, oxygen gas is introduced into the chamber 101 from the oxygen gas supply source 129 of the pressure line 112 through the first pipe, the check valve 115, the second pipe, the filter 118, the third pipe, the valve 124, the fourth pipe, the regulator 127, the fifth pipe, the mass flow controller 132, the sixth pipe, the valve 135, the seventh pipe, the heating unit 137, and the eighth pipe 151. At the same time, the inside of the chamber 101 is pressurized while being set to an oxygen atmosphere by means of gradually closing the variable valve 139 in the pressure adjusting line. Then, the inside of the chamber 101 is pressurized to a predetermined pressure lower than 1 MPa and kept at this pressure.

Next, the PZT film of the substrate to be poled 102 is irradiated with lamp light from the lamp heater 108. Thereby, the PZT film is heated rapidly to the crystallization temperature (e.g., 600° C.), and kept for 1 minute at the crystallization temperature. As a result, the PZT rapidly reacts with oxygen and the PZT film is crystallized.

Subsequently, the poling treatment is applied to the crystallized PZT film by the same method as any of the methods in the first to fourth embodiments.

For example, the oxygen supply from the oxygen supply source of the pressure line 112 is terminated and the inside of the chamber 101 is exhausted into vacuum by the exhaustion pump. Subsequently, the plasma forming gas such as Ar in a shower state is introduced into the chamber 101 from the supply ports of the gas shower electrode 107 and supplied onto the surface of the PZT film. This supplied plasma forming gas is exhausted to the outside of the chamber 101 by the exhaustion pump through a space between the holding electrode 4 and the earth shield 5. Then, the inside of the chamber 1 is set to a plasma forming gas atmosphere by controlling a pressure and a plasma forming gas flow rate into predetermined values by means of the balance between a plasma forming gas supply amount and the exhaustion, a high frequency (RF) power of 380 kHz and 13.56 MHz, for example, is applied by the high frequency power source 6 to generate plasma, and thereby the poling treatment is applied to the PZT film. Preferably, this poling treatment is performed in the following conditions: the pressure is 0.01 Pa to the air pressure; the power source is a DC power source, the high-frequency power source, or a microwave power source; the treatment temperature is not lower than the Curie temperature of the PZT film (preferably not lower than a temperature higher than the Curie temperature by 50° C.), not lower than a temperature at which the residual polarization value Pr (μC/cm²) in the hysteresis curve of the PZT film becomes 0%, or not lower than 100° C. (preferably not lower than 150° C. and more preferably not lower than 250° C.); and the DC voltage component in the plasma formation is ±50 V to ±2 kV. Subsequently, after the poling treatment has been performed for a predetermined time, the supply of the plasma forming gas from the supply ports of the gas shower electrode 107 is terminated and the poling treatment is finished.

According to the present embodiment, after the PZT film has been heated to the crystallization temperature to be crystallized by the irradiation of the lamp light from the lamp heater 108, without decreasing the temperature of the PZT film to the room temperature, plasma is formed continuously at a position facing the PZT film of the substrate to be poled 102, and the poling treatment is applied to the PZT film at a temperature lower than the crystallization temperature and also not lower than the Curie temperature. Accordingly, it is possible to carry out the crystallization treatment and the poling treatment efficiently.

Note that the present embodiment may be changed as described in the following to be carried out.

By means of forming plasma at a position facing the PZT film while the PZT film is heated to the crystallization temperature by the irradiation of the lamp light from the lamp heater, the poling treatment may be applied to the PZT film while crystallizing the PZT film.

Further, the present embodiment may be carried out in combination with the first to sixth embodiments. For example, the poling treatment may be performed while the temperature is decreased from a first temperature which is not lower than the Curie temperature of the PZT film (preferably not lower than a temperature higher than the Curie temperature by 50° C.), not lower than a temperature at which the residual polarization value Pr (μC/cm²) in the hysteresis curve of the PZT film becomes 0%, or not lower than 100° C. (preferably not lower than 150° C., and more preferably not lower than 250° C.), to a second temperature. The second temperature may be a temperature not lower than a temperature at which the residual polarization value becomes 50% of a residual polarization value at the room temperature in the hysteresis curve of the PZT film and also lower than the first temperature, not lower than 50° C. and also lower than the first temperature, or not lower than 100° C. and also lower than the first temperature.

### Example

Spin coating was performed by the use of 25% by weight of sol-gel PZT solution with 15% excessive Pb (Pb/Zr/Ti=115/52/48). Thereby, the PZT solution was coated on a wafer. A coating amount is 500 μL for one time, and PZT thick film coating was performed by the use of the following spin condition.

### (Spin Condition)

Increase from 0 to 300 rpm in 3 seconds and keeping for 3 seconds

Increase from 300 to 500 rpm in 5 seconds and keeping for 5 seconds

Increase from 500 to 1,500 rpm in 5 seconds and keeping for 90 seconds

For every coating, the coated film was kept on a hotplate heated to 250° C. for 30 seconds as a drying (water removal) process and water was removed. Next, for calcination process, vacuuming was performed by a rotary pump and an attained vacuum was 10⁻¹ Pa. Next, N₂ was introduced to have the air pressure and the coated film was heated to 450° C. for 90 seconds for decomposition and removal of an organic component.

The above coating, drying, and calcination were repeated 3, 6, 9, 12, and 15 times, crystallization treatment was performed in an oxygen atmosphere at 700° C. for 5 minutes in a sintering furnace, and PZT thick films were fabricated having a total film thickness of 1, 2, 3, 4, and 5 μm.

The polarization treatment was applied to the PZT thick films fabricated by the above sol-gel method, by the use of the plasma poling device shown in FIG. 1.

An RF power source of 380 kHz and 13.56 MHz was used as the power source. The treatment condition was changed depending on the PZT film thickness, and the treatment was performed in the following conditions: a pressure of 1 to 30 Pa, an RF output of 70 to 700 W, an AR gas flow rate of 15 to 30 sccm, a temperature of 25° C., and a treatment time of 1 to 5 minutes. Basically, with reference to a Vdc monitor of the RF power source, the treatment was performed in the condition of Vdc=50 V for each film thickness of 1 μm. That is, for film thicknesses of 1, 2, 3, 4, and 5 μm, Vdc values were 50, 100, 150, 200, and 250 V, respectively. The treatment was performed for 1 minute for each of the PZT films.

As a result, when measured by a commercial d33 meter, the piezoelectric characteristic d33 were improved significantly from d33 values of 14, 23, 14, 8, and 13 μm/V before the polarization treatment to d33 values of 450, 420, 350, 440, and 400 μm/V after the polarization treatment.

Accordingly, it was confirmed that the piezoelectric characteristics were improved considerably by means of forming plasma at a position facing the PZT thick film and applying the poling treatment to the PZT thick film.

### DESCRIPTION OF THE SYMBOLS

1 . . . Poling chamber
2 . . . Substrate to be poled, Substrate
3 . . . Plasma forming gas supply mechanism
4 . . . Holding electrode
5 . . . Earth shield
6, 6a, 6b . . . High frequency power source
7 . . . Gas shower electrode (Opposite electrode)
8a, 8b . . . Switch
9 . . . Transfer chamber
10 . . . LL chamber
11 . . . Poling chamber
12 . . . CVD chamber
13 . . . Spin coater chamber
14 . . . RTA chamber
15, 28, 41 . . . Chamber
16a . . . Sputtered particles
16b . . . Poling gas
16c . . . CVD gas
16d . . . Evaporation material
17, 29, 42 . . . Holding electrode
18 . . . High frequency power source for poling
19, 30 . . . Opposite electrode
20 . . . High frequency power source for sputtering
21 . . . Poling gas supply source
22 . . . Sputter gas supply source
23 to 25 . . . Valve
26 . . . Vacuum exhaustion mechanism
27a to 27d . . . Switch
28 . . . Chamber
31. High frequency power source for CVD
32 . . . CVD gas supply source
33 . . . Crystal
35 . . . A pair of electrodes
36 . . . Oil
37 . . . Oil bath
38 . . . Heater
39 . . . High voltage power source
40 . . . Lead wire
43 . . . Evaporation source
51 . . . Hysteresis curve having a residual polarization value Pr of 100%
52 . . . Hysteresis curve having a residual polarization value Pr of 50%
101 . . . Chamber
102 . . . Substrate to be poled, Substrate
103 . . . Plasma forming gas supply mechanism
104 . . . Holding electrode
105 . . . Earth shield
107 . . . Gas shower electrode (Opposite electrode)
108 . . . Lamp heater
112 . . . Pressure line
113 . . . Argon gas supply source
114 to 116, 144 . . . Check valve
117 to 119 . . . Filter
120 to 122 . . . Pressure gauge
123 to 125 . . . Valve
126 to 128 . . . Regulator
129 . . . Oxygen gas supply source
131 to 133 . . . Mass flow controller
134 to 136 . . . Valve
137 . . . Heating unit
138 . . . Nitrogen gas supply source
139 . . . Variable valve
140 . . . Pressure gauge
141, 142 . . . Release valve
143 . . . Leak valve
145 . . . Nitrogen gas supply source
151 . . . Eighth pipe
152 . . . Ninth pipe
169 . . . Valve
170 . . . Vacuum pump

1. A poling treatment method for applying a poling treatment to a substrate to be poled at a first temperature, wherein
said first temperature is not lower than a temperature at which a residual polarization value in a hysteresis curve of said substrate to be poled becomes 0%.

2. The poling treatment method according to claim 1, wherein
said poling treatment is applied to said substrate to be poled while a temperature is decreased from said first temperature to a second temperature or while the temperature is increased from said second temperature to said first temperature, and
said second temperature is not lower than a temperature at which a residual polarization value becomes 50% of a residual polarization value at a room temperature in the hysteresis curve of said substrate to be poled, and also lower than said first temperature.

3. A poling treatment method for applying a poling treatment to a substrate to be poled at a first temperature, wherein
said first temperature is not lower than a Curie temperature.

4. The poling treatment method according to claim 3, wherein
said poling treatment is applied to said substrate to be poled while a temperature is decreased from said first temperature to a second temperature, or while the temperature is increased from said second temperature to said first temperature, and
said second temperature is not lower than 50° C. and also lower than said first temperature.

5. A poling treatment method for applying a poling treatment to a substrate to be poled at a first temperature, wherein
said first temperature is not lower than 100° C.

6. The poling treatment method according to claim 5, wherein
said poling treatment is applied to said substrate to be poled while a temperature is decreased from said first temperature to a second temperature, or while the temperature is increased from said second temperature to said first temperature, and
said second temperature is not lower than 100° C. and also lower than said first temperature.

7. The poling treatment method according to claim 1, wherein
said substrate to be poled is the one in which a piezoelectric material film is formed on a silicon wafer having a thickness smaller than a thickness of the SEMI standard or a silicon wafer having a thickness not larger than 400 μm.

8. The poling treatment method according to claim 1, wherein
said substrate to be poled is the one in which a piezoelectric material film is formed on any substrate of a metal substrate, a metal substrate having an oxidation resistance, a metal substrate having a heat resistance against the Curie temperature of said substrate to be poled or the temperature at which the residual polarization value in the hysteresis curve of said substrate to be poled becomes 0%, an iron based substrate, and an Ni based substrate.

9. The poling treatment method according to claim 1, wherein
said substrate to be poled is the one in which a piezoelectric material film is formed on any substrate of a glass substrate, a glass substrate having an oxidation resistance, and a glass substrate having a heat resistance against the Curie temperature of said substrate to be poled or the temperature at which the residual polarization value in the hysteresis curve of said substrate to be poled becomes 0%.

10. A poling treatment method for applying a poling treatment to a substrate to be poled, wherein
said substrate to be poled is the one in which a piezoelectric material film is formed on a silicon wafer having a thickness smaller than a thickness of the SEMI standard or a silicon wafer having a thickness not larger than 400 μm.

11. The poling treatment method according to claim 1, wherein
said substrate to be poled is a substrate including a dielectric body or an insulating body.

12. The poling treatment method according to claim 1, wherein
said substrate to be poled is a substrate including a piezoelectric body.

13. The poling treatment method according to claim 1, wherein
said substrate to be poled is a substrate including a pyroelectric body.

14. The poling treatment method according to claim 1, wherein
said substrate to be poled is a substrate including a ferroelectric body.

15. The poling treatment method according to claim 1, wherein
plasma is formed at a position facing said substrate to be poled when the poling treatment is applied to said substrate to be poled.

16. The poling treatment method according to claim 15, wherein
a DC voltage when a DC plasma is formed at a position facing said substrate to be poled, or a DC voltage component when a high frequency plasma is formed at a position facing said substrate to be poled, is ±50 V to ±2 kV.

17. The poling treatment method according to claim 15, wherein
a pressure when said plasma is formed is 0.01 Pa to an air pressure.

18. The poling treatment method according to claim 15, wherein
a plasma forming gas when said plasma is formed is one or more kinds of gas selected from a group of inert gas, H₂, N₂, O₂, F₂, CₓH_{y}, CₓF_{y}, and air.

19. A piezoelectric body, wherein
the poling treatment is applied to said substrate to be poled by the poling treatment method according to claim 1 and said substrate to be poled is provided with piezoelectric activity.

20. A plasma poling device, comprising:
a poling chamber;
a holding electrode which is disposed in said poling chamber and holds a substrate to be poled;
an opposite electrode which is disposed in said poling chamber and disposed facing said substrate to be poled held on said holding electrode;
a power source electrically connected to one electrode of said holding electrode and said opposite electrode;
a gas supply mechanism supplying a plasma forming gas to a space between said opposite electrode and said holding electrode;
a temperature control mechanism controlling a temperature of said substrate to be poled held on said holding electrode; and
a control unit controlling said power source, said gas supply mechanism, and said temperature control mechanism, wherein
said control unit controls said power source, said gas supply mechanism, and said temperature control mechanism so as to set a temperature of said substrate to be poled to a first temperature not lower than a temperature at which a residual polarization value in a hysteresis curve of said substrate to be poled becomes 0%, and to form a plasma at a position facing said substrate to be poled and apply the poling treatment to said substrate to be poled.

21. A plasma poling device, comprising:
a poling chamber;
a holding electrode which is disposed in said poling chamber and holds a substrate to be poled;
an opposite electrode which is disposed in said poling chamber and disposed facing said substrate to be poled held on said holding electrode;
a first power source and a ground potential connected to said holding electrode via a first switch;
a second power source and said ground potential connected to said opposite electrode via a second switch;
a gas supply mechanism supplying a plasma forming gas to a space between said opposite electrode and said holding electrode;
a temperature control mechanism controlling a temperature of said substrate to be poled held on said holding electrode; and
a control unit controlling said first power source, said second power source, said gas supply mechanism, and said temperature control mechanism, wherein
said first switch switches from a first state in which said holding electrode and said first power source are electrically connected to each other, to a second state in which said holding electrode and said ground potential are electrically connected to each other,
said second switch switches from a third state in which said opposite electrode and said ground potential are electrically connected to each other, to a fourth state in which said opposite electrode and said second power source are electrically connected to each other, and
said control unit controls said first power source, said second power source, said gas supply mechanism, and said temperature control mechanism so as to set a temperature of said substrate to be poled to a first temperature not lower than a temperature at which a residual polarization value in a hysteresis curve of said substrate to be poled becomes 0%, and to form a plasma at a position facing said substrate to be poled and apply a poling treatment to said substrate to be poled, in said first state and said third state or in said second state and said fourth state.

22. The plasma poling device according to claim 20, wherein
said control unit is controlled so as to apply said poling treatment to said substrate to be poled, while decreasing a temperature from said first temperature to a second temperature or while increasing the temperature from said second temperature to said first temperature, and
said second temperature is not lower than a temperature at which the residual polarization value becomes 50% of a residual polarization value at a room temperature in the hysteresis curve of said substrate to be poled, and also lower than said first temperature.

23. A plasma poling device, comprising:
a poling chamber;
a holding electrode which is disposed in said poling chamber and holds a substrate to be poled;
an opposite electrode which is disposed in said poling chamber and disposed facing said substrate to be poled held on said holding electrode;
a power source electrically connected to one electrode of said holding electrode and said opposite electrode;
a gas supply mechanism supplying a plasma forming gas to a space between said opposite electrode and said holding electrode;
a temperature control mechanism controlling a temperature of said substrate to be poled held on said holding electrode; and
a control unit controlling said power source, said gas supply mechanism, and said temperature control mechanism, wherein
said control unit controls said power source, said gas supply mechanism, and said temperature control mechanism so as to set a temperature of said substrate to be poled to a first temperature not lower than a Curie temperature, and to form a plasma at a position facing said substrate to be poled and apply a poling treatment to said substrate to be poled.

24. A plasma poling device, comprising:
a poling chamber;
a holding electrode which is disposed in said poling chamber and holds a substrate to be poled;
an opposite electrode which is disposed in said poling chamber and disposed facing said substrate to be poled held on said holding electrode;
a first power source and a ground potential connected to said holding electrode via a first switch;
a second power source and said ground potential connected to said opposite electrode via a second switch;
a gas supply mechanism supplying a plasma forming gas to a space between said opposite electrode and said holding electrode;
a temperature control mechanism controlling a temperature of said substrate to be poled held on said holding electrode; and
a control unit controlling said first power source, said second power source, said gas supply mechanism, and said temperature control mechanism, wherein
said first switch switches from a first state in which said holding electrode and said first power source are electrically connected to each other, to a second state in which said holding electrode and said ground potential are electrically connected to each other,
said second switch switches from a third state in which said opposite electrode and said ground potential are electrically connected to each other, to a fourth state in which said opposite electrode and said second power source are electrically connected to each other, and
said control unit controls said first power source, said second power source, said gas supply mechanism, and said temperature control mechanism so as to set a temperature of said substrate to be poled to a first temperature not lower than a Curie temperature, and to form a plasma at a position facing said substrate to be poled and apply a poling treatment to said substrate to be poled, in said first state and said third state or in said second state and said fourth state.

25. The plasma poling device according to claim 23, wherein
said control unit is controlled so as to apply said poling treatment to said substrate to be poled, while decreasing a temperature from said first temperature to a second temperature or while increasing the temperature from said second temperature to said first temperature, and
said second temperature is not lower than 50° C. and also lower than said first temperature.

26. A plasma poling device, comprising:
a poling chamber;
a holding electrode which is disposed in said poling chamber and holds a substrate to be poled;
an opposite electrode which is disposed in said poling chamber and disposed facing said substrate to be poled held on said holding electrode;
a power source electrically connected to one electrode of said holding electrode and said opposite electrode;
a gas supply mechanism supplying a plasma forming gas to a space between said opposite electrode and said holding electrode;
a temperature control mechanism controlling a temperature of said substrate to be poled held on said holding electrode; and
a control unit controlling said power source, said gas supply mechanism, and said temperature control mechanism, wherein
said control unit controls said power source, said gas supply mechanism, and said temperature control mechanism so as to set a temperature of said substrate to be poled to a first temperature not lower than 100° C., and to form a plasma at a position facing said substrate to be poled and apply a poling treatment to said substrate to be poled.

27. A plasma poling device, comprising:
a poling chamber;
a holding electrode which is disposed in said poling chamber and holds a substrate to be poled;
an opposite electrode which is disposed in said poling chamber and disposed facing said substrate to be poled held on said holding electrode;
a first power source and a ground potential connected to said holding electrode via a first switch;
a second power source and said ground potential connected to said opposite electrode via a second switch;
a gas supply mechanism supplying a plasma forming gas to a space between said opposite electrode and said holding electrode;
a temperature control mechanism controlling a temperature of said substrate to be poled held on said holding electrode; and
a control unit controlling said first power source, said second power source, said gas supply mechanism, and said temperature control mechanism, wherein
said first switch switches from a first state in which said holding electrode and said first power source are electrically connected to each other, to a second state in which said holding electrode and said ground potential are electrically connected to each other,
said second switch switches from a third state in which said opposite electrode and said ground potential are electrically connected to each other, to a fourth state in which said opposite electrode and said second power source are electrically connected to each other, and
said control unit controls said first power source, said second power source, said gas supply mechanism, and said temperature control mechanism so as to set a temperature of said substrate to be poled to a first temperature not lower than 100° C., and to form a plasma at a position facing said substrate to be poled and apply a poling treatment to said substrate to be poled, in said first state and said third state or in said second state and said fourth state.

28. The plasma poling device according to claim 26, wherein
said control unit is controlled so as to apply said poling treatment to said substrate to be poled, while decreasing a temperature from said first temperature to a second temperature or while increasing the temperature from said second temperature to said first temperature, and
said second temperature is not lower than 100° C. and also lower than said first temperature.

29. The plasma poling device according to claim 20, wherein
said substrate to be poled is the one in which a piezoelectric material film is formed on a silicon wafer having a thickness smaller than a thickness of the SEMI standard or a silicon wafer having a thickness not larger than 400 μm.

30. The plasma poling device according to claim 20, wherein
said substrate to be poled is the one in which a piezoelectric material film is formed on any substrate of a metal substrate, a metal substrate having an oxidation resistance, a metal substrate having a heat resistance against the Curie temperature of said substrate to be poled or the temperature at which the residual polarization value in the hysteresis curve of said substrate to be poled becomes 0%, an iron based substrate, and an Ni based substrate.

31. The plasma poling device according to claim 20, wherein
said substrate to be poled is the one in which a piezoelectric material film is formed on any substrate of a glass substrate, a glass substrate having an oxidation resistance, and a glass substrate having a heat resistance against the Curie temperature of said substrate to be poled or the temperature at which the residual polarization value in the hysteresis curve of said substrate to be poled becomes 0%.

32. The plasma poling device according to claim 20, wherein
said substrate to be poled is a substrate including a dielectric body or an insulating body.

33. The plasma poling device according to claim 20, wherein
said substrate to be poled is a substrate including a piezoelectric body.

34. The plasma poling device according to claim 20, wherein
said substrate to be poled is a substrate including a pyroelectric body.

35. The plasma poling device according to claim 20, wherein
said substrate to be poled is a substrate including a ferroelectric body.

36. The plasma poling device according to claim 20, wherein
a DC voltage for forming a DC plasma or a DC voltage component for forming a high frequency plasma when power is supplied to one electrode of said holding electrode and said opposite electrode, is ±50 V to ±2 kV.

37. The plasma poling device according to claim 20, comprising
a pressure control mechanism controlling a pressure inside said poling chamber to 0.01 Pa to an air pressure when said poling treatment is performed.

38. The plasma poling device according to claim 20, wherein
said plasma forming gas is one or more kinds of gas selected from a group of inert gas, H₂, N₂, O₂, F₂, CₓH_{y}, CₓF_{y}, and air.

39. A piezoelectric body, wherein
a poling treatment is applied to said substrate to be poled by the plasma poling device according to claim 20, and said substrate to be poled is provided with piezoelectric activity.

40. A film forming device, comprising
the plasma poling device according to claim 20.

41. The film forming device according to claim 40, wherein
said film forming device is any one of a spin coating device, a lamp annealing device, a sputtering device, a CVD device, and an evaporation device.

42. An etching device, comprising
the plasma poling device according to claim 20.

43. A lamp annealing device, comprising:
a chamber;
a holding electrode which is disposed in said chamber and holds a substrate to be poled including any film of a dielectric material film, an insulating material film, a piezoelectric material film, a pyroelectric material film, and a ferroelectric material film;
an opposite electrode which is disposed in said chamber and disposed facing said substrate to be poled held on said holding electrode;
a lamp heater irradiating said substrate to be poled with lamp light;
a power source electrically connected to one electrode of said holding electrode and said opposite electrode;
a gas supply mechanism supplying a plasma forming gas to a space between said opposite electrode and said holding electrode; and
a control unit controlling said lamp heater, said power source, and said gas supply mechanism.

44. The lamp annealing device according to claim 43, wherein
said control unit controls said lamp heater, said power source, and said gas supply mechanism, so that said substrate to be poled is heated to a crystallization temperature and any of said films is crystallized by the irradiation of the lamp light from said lamp heater, and so that a plasma is formed at a position facing said substrate to be poled and a poling treatment is applied to said substrate to be poled at a first temperature lower than said crystallization temperature and also not lower than a temperature at which a residual polarization value in a hysteresis curve of said substrate to be poled becomes 0%.

45. The lamp annealing device according to claim 43, wherein
said control unit controls said lamp heater, said power source, and said gas supply mechanism, so that said substrate to be poled is heated to a crystallization temperature and any of said films is crystallized by the irradiation of the lamp light from said lamp heater, and so that a plasma is formed at a position facing said substrate to be poled and a poling treatment is applied to said substrate to be poled at a first temperature lower than said crystallization temperature and also not lower than a Curie temperature.

46. The lamp annealing device according to claim 43, wherein
said control unit controls said lamp heater, said power source, and said gas supply mechanism, so that said substrate to be poled is heated to a crystallization temperature and any of said films is crystallized by the irradiation of the lamp light from said lamp heater, and so that a plasma is formed at a position facing said substrate to be poled and a poling treatment is applied to said substrate to be poled at a first temperature lower than said crystallization temperature and also not lower than 100° C.

47. The lamp annealing device according to claim 43, wherein
said control unit controls said lamp heater, said power source, and said gas supply mechanism, so that a plasma is formed at a position facing said substrate to be poled while said substrate to be poled is heated to a crystallization temperature by the irradiation of the lamp light from said lamp heater, and thereby a poling treatment is applied to said substrate to be poled while any of said films is crystallized.

48. A lamp annealing device, comprising:
a chamber;
a holding electrode which is disposed in said chamber and holds a substrate to be poled including any film of a dielectric material film, an insulating material film, a piezoelectric material film, a pyroelectric material film, and a ferroelectric material film;
an opposite electrode which is disposed in said chamber and disposed facing said substrate to be poled held on said holding electrode;
a lamp heater irradiating said substrate to be poled with lamp light;
a first power source and a ground potential connected to said holding electrode via a first switch;
a second power source and said ground potential connected to said opposite electrode via a second switch;
a gas supply mechanism supplying a plasma forming gas to a space between said opposite electrode and said holding electrode; and
a control unit controlling said lamp heater, said first power source, said second power source, and said gas supply mechanism, wherein
said first switch switches from a first state in which said holding electrode and said first power source are electrically connected to each other, to a second state in which said holding electrode and said ground potential are electrically connected to each other,
said second switch switches from a third state in which said opposite electrode and said ground potential are electrically connected to each other, to a fourth state in which said opposite electrode and said second power source are electrically connected to each other.

49. The lamp annealing device according to claim 48, wherein
said control unit controls said lamp heater, said first power source, said second power source and said gas supply mechanism, so that said substrate to be poled is heated to a crystallization temperature and any of said films is crystallized by the irradiation of the lamp light from said lamp heater, and so that a plasma is formed at a position facing said substrate to be poled in said first state and said third state or in said second state and said fourth state and a poling treatment is applied to said substrate to be poled at a first temperature lower than said crystallization temperature and also not lower than a temperature at which a residual polarization value in a hysteresis curve of said substrate to be poled becomes 0%.

50. The lamp annealing device according to claim 48, wherein
said control unit controls said lamp heater, said first power source, said second power source and said gas supply mechanism, so that said substrate to be poled is heated to a crystallization temperature and any of said films is crystallized by the irradiation of the lamp light from said lamp heater, and so that a plasma is formed at a position facing said substrate to be poled in said first state and said third state or in said second state and said fourth state and a poling treatment is applied to said substrate to be poled at a first temperature lower than said crystallization temperature and also not lower than a Curie temperature.

51. The lamp annealing device according to claim 48, wherein
said control unit controls said lamp heater, said first power source, said second power source, and said gas supply mechanism, so that said substrate to be poled is heated to a crystallization temperature and any of said films is crystallized by the irradiation of the lamp light from said lamp heater, and so that a plasma is formed at a position facing said substrate to be poled in said first state and said third state or in said second state and said fourth state and a poling treatment is applied to said substrate to be poled at a first temperature lower than said crystallization temperature and also not lower than 100° C.

52. The lamp annealing device according to claim 48, wherein
said control unit controls said lamp heater, said first power source, said second power source, and said gas supply mechanism, so that a plasma is formed at a position facing said substrate to be poled in said first state and said third state or in said second state and said fourth state while said substrate to be poled is heated to a crystallization temperature by the irradiation of the lamp light from said lamp heater, and thereby a poling treatment is applied to said substrate to be poled while any of said films is crystallized.

53. The lamp annealing device according to claim 44, wherein
said control unit is controlled so as to apply said poling treatment to said substrate to be poled while decreasing a temperature from said first temperature to a second temperature, and
said second temperature is not lower than a temperature at which a residual polarization value becomes 50% of a residual polarization value at a room temperature in the hysteresis curve of said substrate to be poled, and also lower than said first temperature.

54. The lamp annealing device according to claim 45, wherein
said control unit is controlled so as to apply said poling treatment to said substrate to be poled while decreasing a temperature from said first temperature to a second temperature, and
said second temperature is not lower than 50° C. and also lower than said first temperature.

55. The lamp annealing device according to claim 46, wherein
said control unit is controlled so as to apply said poling treatment to said substrate to be poled while decreasing a temperature from said first temperature to a second temperature, and
said second temperature is not lower than 100° C. and also lower than said first temperature.

56. The lamp annealing device according to claim 43, wherein
said substrate to be poled is the one in which any of said films is formed on a silicon wafer having a thickness smaller than a thickness of the SEMI standard or a silicon wafer having a thickness not larger than 400 μm.

57. The lamp annealing device according to claim 43, wherein
said substrate to be poled is the one in which any of said films is formed on any substrate of a metal substrate, a metal substrate having an oxidation resistance, a metal substrate having a heat resistance against the Curie temperature of said substrate to be poled or the temperature at which the residual polarization value in the hysteresis curve of said substrate to be poled becomes 0%, an iron based substrate, and an Ni based substrate.

58. The lamp annealing device according to claim 43, wherein
said substrate to be poled is the one in which any of said films is formed on any substrate of a glass substrate, a glass substrate having an oxidation resistance, and a glass substrate having a heat resistance against the Curie temperature of said substrate to be poled or the temperature at which the residual polarization value in the hysteresis curve of said substrate to be poled becomes 0%.

59. The lamp annealing device according to claim 43, wherein
a DC voltage for forming a DC plasma or a DC voltage component for forming a high frequency plasma when power is supplied to one electrode of said holding electrode and said opposite electrode, is ±50 V to ±2 kV.

60. The lamp annealing device according to claim 43, comprising
a pressure control mechanism controlling a pressure inside said chamber to 0.01 Pa to an air pressure when said poling treatment is performed.

61. The lamp annealing device according to claim 43, wherein
said plasma forming gas is one or more kinds of gas selected from a group of inert gas, H₂, N₂, O₂, F₂, CₓH_{y}, CₓF_{y}, and air.

62. The lamp annealing device according to claim 43, further comprising
a pressure mechanism pressuring an inside of said chamber.

63. The lamp annealing device according to claim 62, wherein
said pressure mechanism includes a gas introduction mechanism introducing pressurized gas into said chamber, and a gas exhaustion mechanism exhausting the gas in said chamber.

64. A manufacturing method of a piezoelectric body for manufacturing a piezoelectric body by applying a poling treatment to a piezoelectric material object at a first temperature, wherein
said first temperature is not lower than a temperature at which a residual polarization value in a hysteresis curve of said piezoelectric material object becomes 0%.

65. The manufacturing method of a piezoelectric body according to claim 64, wherein
said poling treatment is applied to said piezoelectric material object while a temperature is decreased from said first temperature to a second temperature or while the temperature is increased from said second temperature to said first temperature, and
said second temperature is not lower than a temperature at which a residual polarization value becomes 50% of a residual polarization value at a room temperature in the hysteresis curve of said piezoelectric material object, and also lower than said first temperature.

66. A manufacturing method of a piezoelectric body for manufacturing a piezoelectric body by applying a poling treatment to a piezoelectric material object at a first temperature, wherein
said first temperature is not lower than a Curie temperature.

67. The manufacturing method of a piezoelectric body according to claim 66, wherein
said poling treatment is applied to said piezoelectric material object while a temperature is decreased from said first temperature to a second temperature, or while the temperature is increased from said second temperature to said first temperature, and
said second temperature is not lower than 50° C. and also lower than said first temperature.

68. A manufacturing method of a piezoelectric body for manufacturing a piezoelectric body by applying a poling treatment to a piezoelectric material object at a first temperature, wherein
said first temperature is not lower than 100° C.

69. The manufacturing method of a piezoelectric body according to claim 68, wherein
said poling treatment is applied to said piezoelectric material object while a temperature is decreased from said first temperature to a second temperature, or while the temperature is increased from said second temperature to said first temperature, and
said second temperature is not lower than 100° C. and also lower than said first temperature.

70. The manufacturing method of a piezoelectric body according to claim 64, wherein
said piezoelectric material object is the one in which a piezoelectric material film is formed on a substrate, and
said poling treatment is performed by forming a plasma at a position facing said piezoelectric material film.

71. The manufacturing method of a piezoelectric body according to claim 70, wherein
a rear surface of said substrate is polished and a thickness of said substrate is reduced before the piezoelectric material film is formed on said substrate.

72. A manufacturing method of a piezoelectric body, wherein
a rear surface of a substrate is polished and a thickness of said substrate is reduced,
a piezoelectric material film is formed on said substrate, and
a poling treatment is applied to said piezoelectric material film by forming a plasma at a position facing said piezoelectric material film.

73. The manufacturing method of a piezoelectric body according to claim 71, wherein
the thickness of said substrate is not larger than 400 μm after the thickness of the substrate has been reduced.

74. The manufacturing method of a piezoelectric body according to claim 70, which is a manufacturing method of a piezoelectric body for performing said poling treatment using a plasma poling device, wherein
said plasma poling device includes:
a poling chamber;
a holding electrode which is disposed in said poling chamber and holds said substrate;
an opposite electrode which is disposed in said poling chamber and disposed facing said substrate held on said holding electrode;
a power source electrically connected to one electrode of said holding electrode and said opposite electrode;
a gas supply mechanism supplying a plasma forming gas to a space between said opposite electrode and said holding electrode; and
a temperature control mechanism controlling a temperature of said substrate held on said holding electrode.

75. The manufacturing method of a piezoelectric body according to claim 70, which is a manufacturing method of a piezoelectric body for performing said poling treatment using a plasma poling device, wherein
said plasma poling device includes:
a poling chamber;
a holding electrode which is disposed in said poling chamber and holds said substrate;
an opposite electrode which is disposed in said poling chamber and disposed facing said substrate held on said holding electrode;
a first power source and a ground potential connected to said holding electrode via a first switch;
a second power source and said ground potential connected to said opposite electrode via a second switch;
a gas supply mechanism supplying a plasma forming gas to a space between said opposite electrode and said holding electrode; and
a temperature control mechanism controlling a temperature of said substrate held on said holding electrode.

76. A manufacturing method of a piezoelectric body, comprising the steps of:
forming a piezoelectric material film on a substrate;
irradiating said piezoelectric material film with lamp light from a lamp heater, thereby heating said piezoelectric material film to a crystallization temperature to crystallize the film; and
forming a plasma at a position facing said piezoelectric material film and applying a poling treatment to said piezoelectric material film at a first temperature, wherein
said first temperature is lower than said crystallization temperature and also not lower than a temperature at which a residual polarization value in a hysteresis curve of said piezoelectric material film becomes 0%.

77. The manufacturing method of a piezoelectric body according to claim 76, wherein
said poling treatment is applied to said piezoelectric material film while a temperature is decreased from said first temperature to a second temperature, and
said second temperature is not lower than a temperature at which a residual polarization value becomes 50% of a residual polarization value at a room temperature in the hysteresis curve of said piezoelectric material film, and also lower than said first temperature.

78. A manufacturing method of a piezoelectric body, comprising the steps of:
forming a piezoelectric material film on a substrate;
irradiating said piezoelectric material film with lamp light from a lamp heater, thereby heating said piezoelectric material film to a crystallization temperature to crystallize the film; and
forming a plasma at a position facing said piezoelectric material film and applying a poling treatment to said piezoelectric material film at a first temperature, wherein
said first temperature is lower than said crystallization temperature and also not lower than a Curie temperature.

79. The manufacturing method of a piezoelectric body according to claim 78, wherein
said poling treatment is applied to said piezoelectric material film while a temperature is decreased from said first temperature to a second temperature, and
said second temperature is not lower than 50° C. and also lower than said first temperature.

80. A manufacturing method of a piezoelectric body, comprising the steps of:
forming a piezoelectric material film on a substrate;
irradiating said piezoelectric material film with lamp light from a lamp heater, thereby heating said piezoelectric material film to a crystallization temperature to crystallize the film; and
forming a plasma at a position facing said piezoelectric material film and applying a poling treatment to said piezoelectric material film at a first temperature, wherein
said first temperature is lower than said crystallization temperature and also not lower than 100° C.

81. The manufacturing method of a piezoelectric body according to claim 80, wherein
said poling treatment is applied to said piezoelectric material film while a temperature is decreased from said first temperature to a second temperature, and
said second temperature in not lower than 100° C. and also lower than said first temperature.

82. A manufacturing method of a piezoelectric body, comprising the steps of:
forming a piezoelectric material film on a substrate; and
forming a plasma at a position facing said piezoelectric material film while heating said piezoelectric material film to a crystallization temperature by irradiating said piezoelectric material film with lamp light from a lamp heater, and thereby applying a poling treatment to said piezoelectric material film while crystallizing said piezoelectric material film.

83. The manufacturing method of a piezoelectric body according to claim 82, wherein
said poling treatment is applied to said piezoelectric material film while a temperature is decreased from said first temperature to a second temperature, and
said second temperature is a temperature not lower than a temperature at which a residual polarization value becomes 50% of a residual polarization value at a room temperature in a hysteresis curve of said piezoelectric material film, or a temperature not lower than 50° C. and also lower than said crystallization temperature.
